(19) United States
(12) Patent Application Publication
(10) Pub. No.: US 2025/0212644 A1
(43) Pub. Date: Jun. 26, 2025

(54) DISPLAY DEVICE

(71) Applicant: Samsung Display Co., LTD., Yongin-si (KR)

(72) Inventors: Soo Dong KIM, Yongin-si (KR); Jung Hwan YI, Yongin-si (KR)

(73) Assignee: Samsung Display Co., LTD., Yongin-si (KR)

(21) Appl. No.: 18/788,471

(22) Filed: Jul. 30, 2024

(30) Foreign Application Priority Data
Dec. 22, 2023 (KR) 10-2023-0189985

(51) Int. Cl. H10K 59/38; H10K 59/122; H10K 59/80

(52) U.S. Cl. CPC H10K 59/38; H10K 59/122; H10K 59/8731

(57) ABSTRACT

A display device includes a first electrode disposed on a substrate, a pixel-defining layer that covers an edge of the first electrode and defines light-emitting areas and a non-light-emitting area, a light emitting layer disposed on the first electrode and the pixel-defining layer, a second electrode disposed on the light emitting layer, a thin-film encapsulation layer disposed on the second electrode and including a first encapsulation layer, a second encapsulation layer disposed on the first encapsulation layer, and a third encapsulation layer disposed on the second encapsulation layer, and a wavelength conversion layer disposed on the thin-film encapsulation layer and including a bank overlapping the non-light-emitting area, the second encapsulation layer includes first regions overlapping the light-emitting areas and second regions not overlapping the light-emitting areas, and a thickness of the first regions is greater than a thickness of the second regions.

### CROSS-REFERENCE TO RELATED APPLICATION(S)

This application claims priority to and benefits of Korean Patent Application No. 10-2023-0189985 under 35 U.S.C. § 119 filed on Dec. 22, 2023 in the Korean Intellectual Property Office, the entire contents of which are incorporated herein by reference.

### BACKGROUND

### 1. Technical Field

The disclosure relates to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

An organic light-emitting element may include two opposing electrodes and a light emitting layer disposed between the two opposing electrodes. Electrons and holes supplied from the two electrodes are recombined in the light emitting layer to generate excitons, and the generated excitons relax from the excited state to the ground state so that light can be emitted.

An organic light-emitting display device including organic light-emitting elements requires no separate light source such as a backlight unit, and thus it consumes less power and can be made light and thin, as well as exhibiting high-quality characteristics such as wide viewing angle, high luminance and contrast, and fast response speed. Accordingly, an organic light-emitting display device is attracting attention as the next generation display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device that can improve color gamut by reducing color mixing.

It should be noted that objects of the disclosure are not limited to the above-mentioned objects, and other objects will be apparent to those skilled in the art from the following descriptions.

According to an aspect of the disclosure, a display device may include a first electrode disposed on a substrate; a pixel-defining layer that covers an edge of the first electrode and defines light-emitting areas and a non-light-emitting area; a light emitting layer disposed on the first electrode and the pixel-defining layer; a second electrode disposed on the light emitting layer; a thin-film encapsulation layer disposed on the second electrode, the thin-film encapsulation layer comprising a first encapsulation layer, a second encapsulation layer disposed on the first encapsulation layer, and a third encapsulation layer disposed on the second encapsulation layer; and a wavelength conversion layer disposed on the thin-film encapsulation layer, the wavelength conversion layer comprising a bank overlapping the non-light-emitting area, wherein the second encapsulation layer comprises first regions overlapping the light-emitting areas and second regions not overlapping the light-emitting areas, and a thickness of the first regions is greater than a thickness of the second regions.

In an embodiment, the first regions may overlap the non-light-emitting area, and the second regions may overlap the non-light-emitting area.

In an embodiment, the first regions may not overlap the bank and the second regions may overlap the bank.

In an embodiment, the thickness of the second regions may be in a range of about 50% to about 90% of the thickness of the first regions.

In an embodiment, the second encapsulation layer may comprise a groove formed in a surface of the second encapsulation layer, and the groove may be disposed in the second regions.

In an embodiment, the first regions may cover the light-emitting areas and are spaced apart from one another in plan view, and the second regions may be disposed in regions other than the first regions.

In an embodiment, the second regions may be spaced apart from one another and may be disposed between light-emitting areas that emit lights of different colors.

In an embodiment, the display device may further comprise an encapsulation pattern disposed between the second encapsulation layer and the third encapsulation layer, wherein the encapsulation pattern may overlap the first regions but may not overlap the second regions.

In an embodiment, the encapsulation pattern may overlap the light-emitting areas but may not overlap the bank.

In an embodiment, the display device may further comprise a fourth encapsulation layer disposed between the first encapsulation layer and the second encapsulation layer, and a fifth encapsulation layer disposed between the fourth encapsulation layer and the second encapsulation layer, wherein the first encapsulation layer, the third encapsulation layer and the fifth encapsulation layer contain an inorganic material, and the second encapsulation layer and the fourth encapsulation layer contain an organic material.

In an embodiment, the first encapsulation layer and the third encapsulation layer may contain an inorganic material, and the second encapsulation layer may contain an organic material.

In an embodiment, the wavelength conversion layer may comprise a light-transmitting pattern, a first wavelength conversion pattern and a second wavelength conversion pattern that may be disposed in a space defined by the bank and respectively overlapping the light-emitting areas.

In an embodiment, the display device may further comprise a low-refractive layer disposed on the wavelength conversion layer, and a color filter layer disposed on the low-refractive layer, the color filter layer comprising a first color filter overlapping the light-transmitting pattern, a second color filter overlapping the first wavelength conversion pattern, and a third color filter overlapping the second wavelength conversion pattern.

According to an aspect of the disclosure, a display device may include a first electrode disposed on a substrate; a pixel-defining layer that covers an edge of the first electrode and defines light-emitting areas and a non-light-emitting area; a light emitting layer disposed on the first electrode and the pixel-defining layer; a second electrode disposed on the light emitting layer, a thin-film encapsulation layer disposed on the second electrode, the thin-film encapsulation layer comprising a first encapsulation layer, an etch stopper layer disposed on the first encapsulation layer, a second encapsulation layer disposed on the etch stopper layer, and a third encapsulation layer disposed on the second encapsulation layer; and a wavelength conversion layer disposed on the thin-film encapsulation layer, the wavelength conversion layer comprising a bank overlapping the non-light-emitting area, wherein the third encapsulation layer contacts the etch stopper layer in the non-light-emitting area.

In an embodiment, the second encapsulation layer may comprise an opening exposing the etch stopper layer, and the third encapsulation layer contacts the etch stopper layer through the opening of the second encapsulation layer.

In an embodiment, the opening of the second encapsulation layer may overlap the non-light-emitting area and the bank.

In an embodiment, the second encapsulation layer may be disposed between the etch stopper layer and the third encapsulation layer, and may be covered by the etch stopper layer and the third encapsulation layer.

In an embodiment, the display device may further comprise a fourth encapsulation layer disposed between the first encapsulation layer and the etch stopper layer, wherein the second encapsulation layer and the fourth encapsulation layer may contain an organic material.

According to an aspect of the disclosure, a display device may include a first electrode disposed on a substrate; a pixel-defining layer that covers an edge of the first electrode and defines light-emitting areas and a non-light-emitting area; a light emitting layer disposed on the first electrode and the pixel-defining layer; a second electrode disposed on the light emitting layer; a thin-film encapsulation layer disposed on the second electrode, the thin-film encapsulation layer comprising a first encapsulation layer, a second encapsulation layer and an organic layer disposed on the first encapsulation layer and spaced apart from each other, and a third encapsulation layer disposed on the second encapsulation layer and the organic layer; and a wavelength conversion layer disposed on the thin-film encapsulation layer, the wavelength conversion layer comprising a bank overlapping the non-light-emitting area, wherein the third encapsulation layer contacts the etch stopper layer in the non-light-emitting area.

In an embodiment, the second encapsulation layer may overlap the non-light-emitting area and the bank, the second encapsulation layer comprises an opening exposing the first encapsulation layer, and wherein the organic layer is disposed in the opening of the second encapsulation layer contact the first encapsulation layer.

In an embodiment, the third encapsulation layer may cover the second encapsulation layer and the organic layer, and may contact the first encapsulation layer through the opening of the second encapsulation layer.

In an embodiment, the opening of the second encapsulation layer may be filled with the bank on the third encapsulation layer.

In an embodiment, a thickness of the organic layer may be less than a thickness of the second encapsulation layer.

In an embodiment, the first encapsulation layer and the third encapsulation layer may contain an inorganic material, and the second encapsulation layer may contain an organic material.

According to an embodiment of the disclosure, a second region having a groove formed therein is formed in a second encapsulation layer of a thin-film encapsulation layer and a bank is formed on the groove in a display device, so that it is possible to block light exiting from light-emitting areas to adjacent light-emitting areas. Therefore, it is possible to prevent color mixing between the light-emitting areas of the display device to improve the color gamut.

According to an embodiment, an etch stopper layer may be formed on a thin-film encapsulation layer in a display device, so that it is possible to prevent underlying layers from being damaged while an opening of the second encapsulation layer is etched.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment.

FIG. 2 is a view schematically showing lines included in the display device according to an embodiment.

FIG. 3 is a schematic diagram of an equivalent circuit of a sub-pixel according to an embodiment.

FIG. 4 is a schematic cross-sectional view schematically showing a display device according to an embodiment.

FIG. 5 is a schematic cross-sectional view schematically showing a display device according to an embodiment.

FIG. 6 is a schematic cross-sectional view schematically showing a portion of a first light-emitting area of the display device according to an embodiment.

FIG. 7 is a schematic plan view schematically showing an example of light-emitting areas of the display device according to an embodiment.

FIG. 8 is a schematic plan view schematically showing another example of light-emitting areas of the display device according to an embodiment.

FIG. 9 is a schematic cross-sectional view schematically showing a portion of a first light-emitting area of the display device according to an embodiment.

FIG. 10 is a schematic cross-sectional view schematically showing a display device according to an embodiment.

FIG. 11 is a schematic cross-sectional view schematically showing a portion of the first light-emitting area of FIG. 10.

FIG. 12 is a schematic cross-sectional view schematically showing a display device according to an embodiment.

FIG. 13 is a schematic cross-sectional view schematically showing a portion of the first light-emitting area of FIG. 12.

FIG. 14 is a schematic plan view showing a layout of light-emitting areas of a display device according to an embodiment.

FIGS. 15 and 16 are schematic cross-sectional views showing processing steps of a method of fabricating a thin-film encapsulation layer in a display device according to an embodiment.

FIG. 17 is a schematic cross-sectional view showing a display device according to an embodiment.

FIG. 18 is a schematic cross-sectional view schematically showing a portion of the first light-emitting area of FIG. 17.

FIG. 19 is a schematic plan view showing a layout of light-emitting areas of a display device according to an embodiment.

FIG. 20 is a schematic cross-sectional view showing a display device according to an embodiment.

FIG. 21 is a schematic cross-sectional view schematically showing a portion of the first light-emitting area of FIG. 20.

FIG. 22 is a schematic cross-sectional view schematically showing a display device according to an embodiment.

FIG. 23 is a schematic cross-sectional view schematically showing a portion of the first light-emitting area of FIG. 22.

FIG. 24 is a schematic plan view showing a layout of light-emitting areas of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Each of the features of the various embodiments may be combined or combined with each other, in part or in whole, and various variations are possible. Each embodiment may be implemented independently of each other or may be implemented together.

Hereinafter, embodiments will be described with reference to the accompanying drawings.

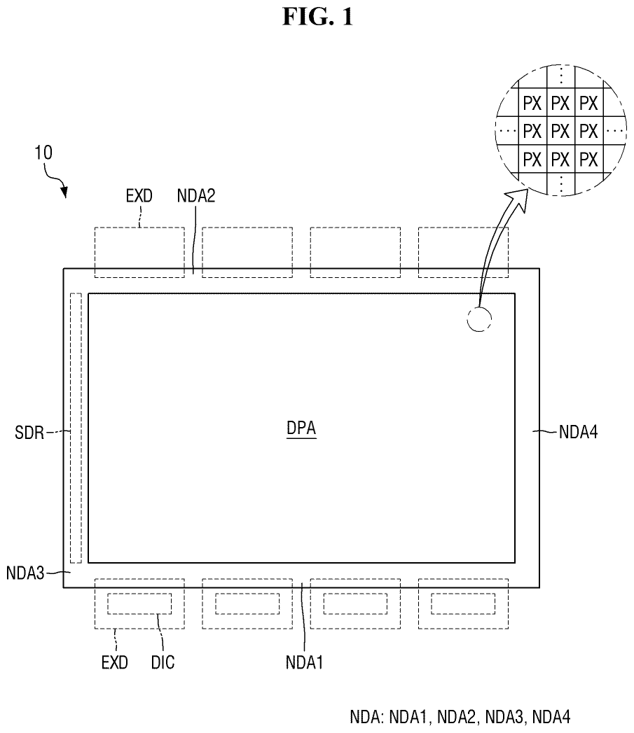

FIG. 1 is a schematic plan view of a display device according to an embodiment.

Referring to FIG. 1, a display device 10 according to an embodiment may be applied to, a smart phone, a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (IoT) devices, etc. In the following description, a television is described as an example of the display device 10. TV may have a high resolution or ultra high resolution such as HD, UHD, 4K and 8K.

The display device 10 according to the embodiments may be variously classified by the way in which images are displayed. Examples of the classification of display device 10 may include an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a cathode ray display device (CRT), a liquid-crystal display device (LCD), an electrophoretic display device (EPD), etc. In the following description, an organic light-emitting display device and an inorganic light-emitting display device will be described as an example of the display device 10, and such light-emitting display devices will be simply referred to as display devices unless it is necessary to discern between them. It is, however, to be understood that embodiments are not limited to the organic light-emitting display device or an inorganic light-emitting display device, and one of the above-listed display devices or any other display device may be employed without departing from the scope of the disclosure.

According to the embodiment, the display device 10 may have a square shape, for example, a rectangular shape when viewed from the top. In case that the display device 10 is a television, it is oriented such that the longer sides are positioned in the horizontal direction. It should be understood, however, that the disclosure is not limited thereto. The longer side may be positioned in the vertical direction. By way of example, the display device 1 may be installed rotatably so that the longer sides are positioned in the horizontal or vertical direction variably.

The display device 10 may include a display area DPA and a non-display area NDA. The display area DPA may be an active area where images are displayed. The display area DPA may have, but is not limited to, a rectangular shape similar to the general shape of the display device 10 when viewed from the top.

The display area DPA may include pixels PX. The pixels PX may be arranged (or disposed) in a matrix. The shape of each of the pixels PX may be, but is not limited to, a rectangle or a square when viewed from the top. Each of the pixels PX may have a diamond shape having sides inclined with respect to a side of the display device 10. The pixels PX may include different color pixels PX. For example, pixels PX may include, but is not limited to, a red first color pixel PX, a green second color pixel PX, and a blue third color pixel PX. The color pixels PX may be arranged alternately in a RGB stripe pattern or a PENTILE™ matrix.

The non-display area NDA may be disposed around the display area DPA. The non-display area NDA may surround the display area DPA entirely or partially. The display area DPA may have a rectangular shape, and the non-display area NDA may be disposed to be adjacent to the four sides of the display area DPA. The non-display area NDA may form the bezel of the display device 10.

In the non-display areas NDA, a driving circuit or a driving element for driving the display area DPA may be disposed. According to an embodiment, a pad area is disposed on the display substrate of the display device 10 in a first non-display area NDA1 disposed adjacent to a first longer side (the lower side in FIG. 1) of the display device 10 and a second non-display area NDA2 adjacent to a second longer side (the upper side in FIG. 1) of the display device 1. An external device EXD may be mounted on a pad electrode of the pad area. Examples of the external devices EXD may include a connection film, a printed circuit board, a driver chip DIC, a connector, a line connection film, etc. A scan driver SDR formed directly on the display substrate of the display device 10 may be disposed in the third non-display area NDA3 disposed adjacent to a first shorter side of the display device 1 (the left side in FIG. 1). It should be understood, however, that the disclosure is not limited thereto. The scan driver SDR may be disposed on a second shorter side (right side in FIG. 1) of the display device 10. FIG. 1 also illustrates a fourth non-display area NDA4.

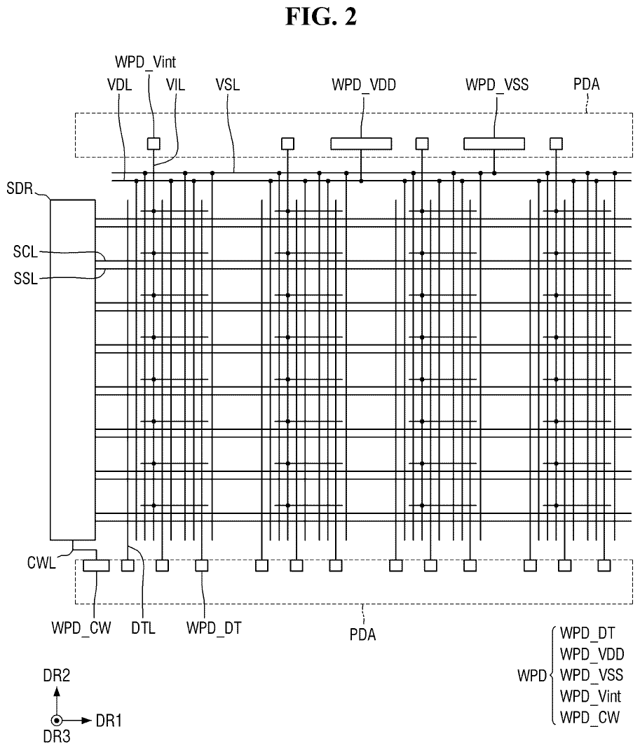

FIG. 2 is a view schematically showing lines included in the display device according to an embodiment.

Referring to FIG. 2, the display device 10 may include plural lines. The lines may include a scan line SCL, a sensing line SSL, a data line DTL, an initialization voltage line VIL, a first voltage line VDL, a second voltage line VSL, etc. Although not shown in the drawings, other lines may be further disposed in the display device 10.

The scan line SCL and the sensing line SSL may be extended in the first direction DR1. The scan line SCL and the sensing line SSL may be connected to a scan driver SDR. The scan driver SDR may include a driving circuit. The scan driver SDR may be disposed on, but is not limited to, one side or a side of the display area DPA in the first direction DR1. The scan driver SDR may be connected to a signal connection line CWL, and at least one end or an end of the signal connection line CWL may form a pad WPD_CW on a pad area PDA in the non-display area to be connected to an external device.

As used herein, in case that an element is referred to as being “connected” or “coupled” to another element, it can be directly connected or coupled to the element or intervening elements may be present. Such elements may be understood as a single integrated element and thus one portion thereof is connected to another portion. Moreover, in case that an element is referred to as being “connected” to another element, it may be in direct contact with the element and also electrically connected to the element.

The data line DTL and the initialization voltage line VIL may be extended in a second direction DR2 crossing (or intersecting) the first direction DR1. The initialization voltage line VIL may further include branches as well as the portion extended in the second direction DR2. Each of the first voltage line VDL and the second voltage line VSL may also include portions extended in the second direction DR2 and portions connected thereto and extended in the first direction DR1. The first voltage line VDL and the second voltage line VSL may have, but is not limited to, a mesh structure. Although not shown in the drawings, each of the pixels PX of the display device 10 may be connected to at least one data line DTL, the initialization voltage line VIL, the first voltage line VDL, and the second voltage line VSL.

The data line DTL, the initialization voltage line VIL, the first voltage line VDL and the second voltage line VSL may be electrically connected to one or more wire pads WPD. The wire pads WPD may be disposed in the pad area PDA. According to an embodiment, a wire pad WPD_DT of the data line DTL (hereinafter referred to as a data pad) may be disposed in the pad area PDA on one side or a side of the display area DPA in the second direction DR2, and a wire pad WPD_Vint of the initialization voltage line VIL (hereinafter referred to as an initialization voltage pad), a wire pad WPD_VDD of the first voltage line VDL (hereinafter referred to as a first power pad), and a wire pad WPD_VSS of the second voltage line VSL (hereinafter referred to as a power pad) may be disposed in the pad area PDA located (or disposed) on the other side of the display area DPA in the second direction DR2. As another example, the data pad WPD_DT, the initialization voltage pad WPD_Vint and the first supply voltage pad WPD_VDD and the second supply voltage pad WPD_VSS may all be disposed in the same area, for example, in the non-display area NDA on the upper side of the display area DPA. External devices EXD may be mounted on the wire pads WPD. The external devices EXD may be mounted on the wire pads WPD by an anisotropic conductive film, ultrasonic bonding, etc.

Each of the pixels PX or sub-pixels SPX of the display device 10 may include a pixel driving circuit, where n is an integer of 1 to 3. The above-described lines may pass through each of the pixels PX or the periphery thereof to apply a driving signal to the pixel driving circuit. The pixel driving circuit may include transistors and a capacitor. The numbers of transistors and capacitors of each pixel driving circuit may be changed in a variety of ways. According to an embodiment, each of the sub-pixels SPX of the display device 10 may have a 3T1C structure, for example, a pixel driving circuit may include three transistors and one capacitor. In the following description, the pixel driving circuit having the 3T1C structure will be described as an example. It is, however, to be understood that the disclosure is not limited thereto. A variety of modified pixel structure may be employed such as a 2T1C structure, a 7T1C structure and a 6T1C structure.

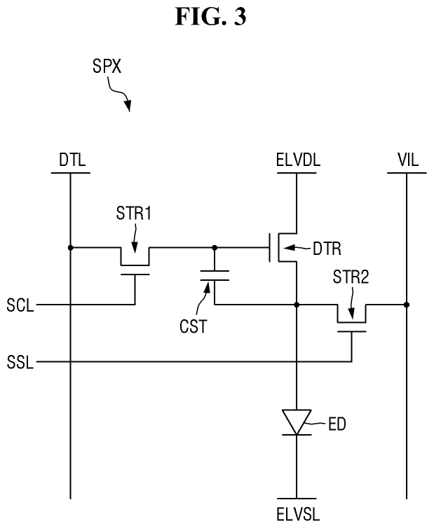

FIG. 3 is a schematic diagram of an equivalent circuit of a sub-pixel according to an embodiment.

Referring to FIG. 3, each of the sub-pixels SPX of the display device 10 according to an embodiment may include three transistors DTR, STR1 and STR2 and one storage capacitor Cst in addition to a light-emitting element ED.

The light-emitting element ED emits light in proportion to the current supplied through the driving transistor DTR. The light-emitting element ED may be implemented as an inorganic light-emitting diode, an organic light-emitting diode, a micro light-emitting diode, a nano light-emitting diode, etc.

The first electrode (for example, the anode electrode) of the light-emitting diode ED may be connected to the source electrode of the driving transistor DTR, and the second electrode (for example, the cathode electrode) thereof may be connected to a second supply voltage line ELVSL, from which a low-level voltage (second supply voltage) is applied, lower than a high-level voltage (first supply voltage) of a first supply voltage line ELVDL.

The driving transistor DTR adjusts a current flowing from the first supply voltage line ELVDL from which the first supply voltage is applied to the light-emitting element ED according to the voltage difference between the gate electrode and the source electrode. The gate electrode of the driving transistor DTR may be connected to a first electrode of the first transistor STR1, the source electrode may be connected to a first electrode of the light-emitting element ED, and the drain electrode may be connected to the first supply voltage line ELVDL from which the first supply voltage is applied.

The first transistor STR1 is turned on by a scan signal of a scan line SCL to connect a data line DTL with the gate electrode of the driving transistor DTR. A gate electrode of the first transistor STR1 may be connected to the scan line SCL, the first electrode thereof may be connected to the gate electrode of the driving transistor DTR, and a second electrode thereof may be connected to the data line DTL.

The second transistor STR2 may be turned on by a sensing signal of a sensing signal line SSL to connect the initialization voltage line VIL to the source electrode of the driving transistor DTR. A gate electrode of the second transistor STR2 may be connected to the sensing signal line SSL, a first electrode thereof may be connected to the initialization voltage line VIL, and a second electrode thereof may be connected to the source electrode of the driving transistor DTR.

According to an embodiment, the first electrode of each of the first and second transistors STR1 and STR2 may be a source electrode while the second electrode thereof may be a drain electrode. It is, however, to be understood that the disclosure is not limited thereto. The first electrode of each of the first and second switching transistors STR1 and STR2 may be a drain electrode while the second electrode thereof may be a source electrode.

The capacitor CST may be formed between the gate electrode and the source electrode of the driving transistor DTR. The storage capacitor CST stores a voltage difference between the gate voltage and the source voltage of the driving transistor DTR.

The driving transistor DTR and the first and second transistors STR1 and STR2 may be formed as thin-film transistors. Although FIG. 3 shows that each of the driving transistor DTR and the first and second switching transistors STR1 and STR2 is implemented as an n-type MOSFET (metal oxide semiconductor field effect transistor), it is to be noted that the disclosure is not limited thereto. For example, the driving transistor DTR and the first and second switching transistors STR1 and STR2 may be implemented as p-type MOSFETs, or some of them may be implemented as n-type MOSFETs while the others may be implemented as p-type MOSFETs.

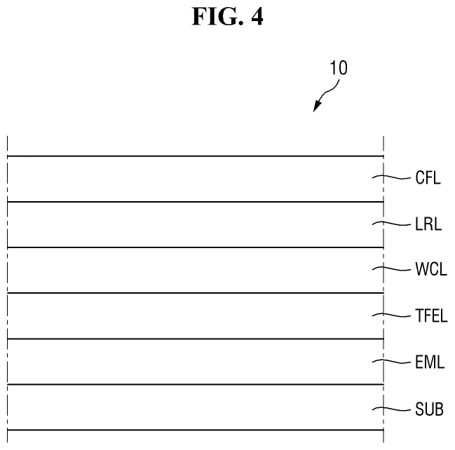

FIG. 4 is a schematic cross-sectional view schematically showing a display device according to an embodiment.

Referring to FIG. 4, the display device 10 according to an embodiment may include a substrate SUB, an emission material layer EML, a thin-film transistor layer TFTL, a wavelength conversion layer WCL, a low-refractive layer LRL, a color filter layer CFL, and an optical functional layer LFL.

The substrate SUB may be an insulating substrate. The substrate SUB may include a transparent material. For example, the substrate SUB may include a transparent insulating material such as glass and quartz. The substrate SUB may be a rigid substrate. The substrate SUB is not limited to those described above. The substrate SUB may include a plastic such as polyimide, or may be flexible so that it can be curved, bent, folded or rolled.

The emission material layer EML may be disposed on the substrate SUB. The emission material layer EML may include switching elements and light-emitting elements ED disposed in each sub-pixel. The switching elements may drive light-emitting elements ED so that the light emitting elements ED emit light.

The thin-film encapsulation layer TFEL may be disposed on the emission material layer EML. The thin-film encapsulation layer TFEL may include an organic film disposed between inorganic films and can protect the emission material layer EML from outside moisture and oxygen.

The wavelength conversion layer WCL may be disposed on the thin-film encapsulation layer TFEL. The wavelength conversion layer WCL may convert the wavelength of light emitted from the emission material layer EML to emit red light, green light and blue light.

The low-refractive layer LRL may be disposed on the wavelength conversion layer WCL. The low-refractive layer LRL may have a relatively low refractive index. Light emitted from below may be refracted toward the top due to a difference in refractive index, so that low-refractive layer LRL can improve the emission efficiency.

The color filter layer CFL may be disposed on the low-refractive layer LRL. The color filter layer CFL can filter light incident from the outside to reduce reflection of external light and improve the color characteristics of light emitted through the wavelength conversion layer WCL.

The optical functional layer LFL may be disposed on the color filter layer CFL. The optical functional layer LFL may be an anti-reflection layer that prevents reflection of external light. The optical functional layer LFL may be attached in the form of a film or formed by coating. It should be understood, however, that the disclosure is not limited thereto. An anti-fingerprint layer or the like may be disposed.

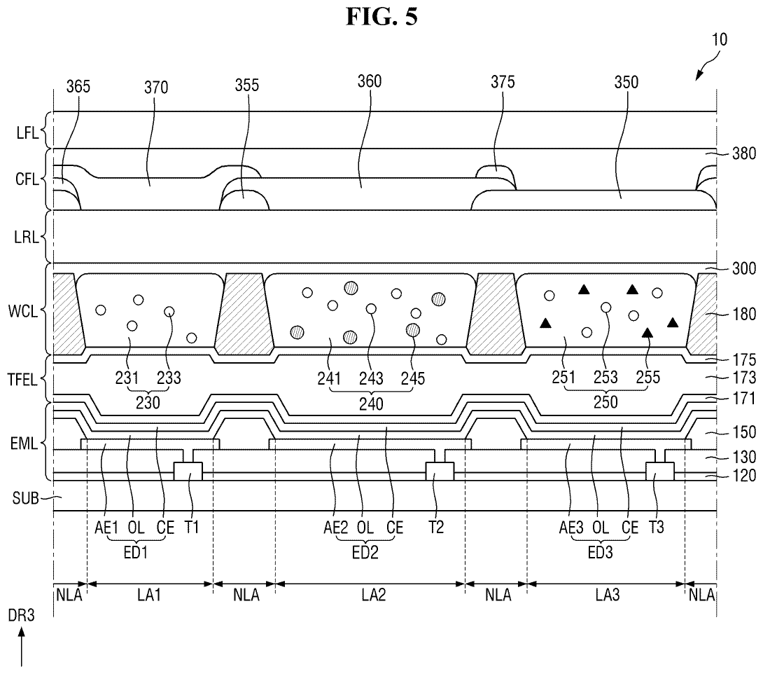

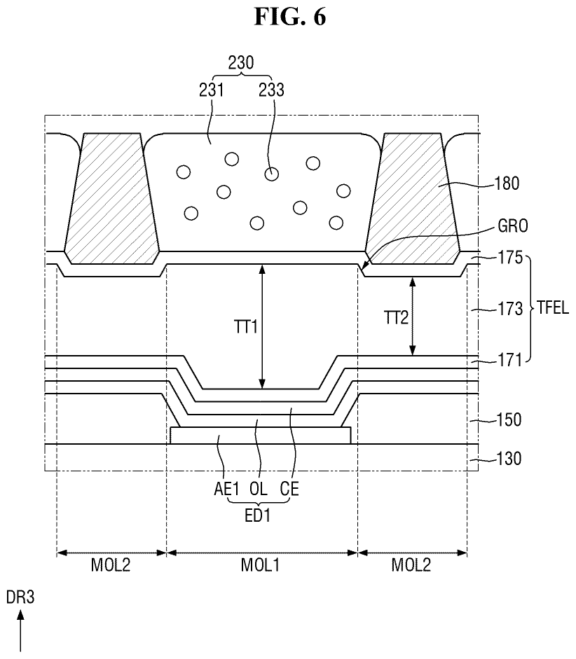

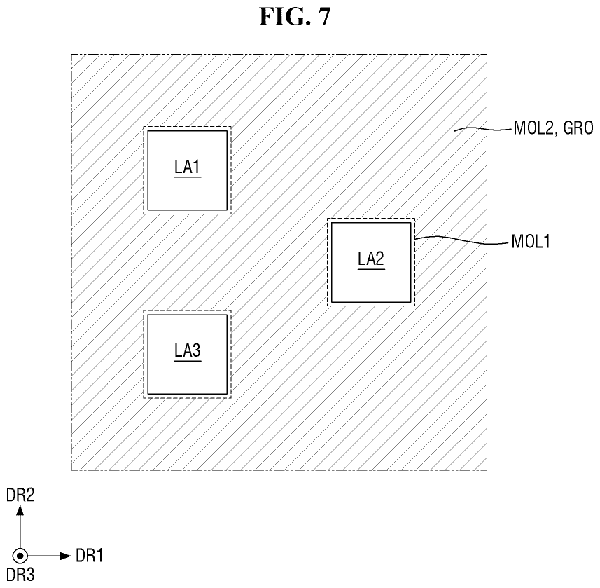

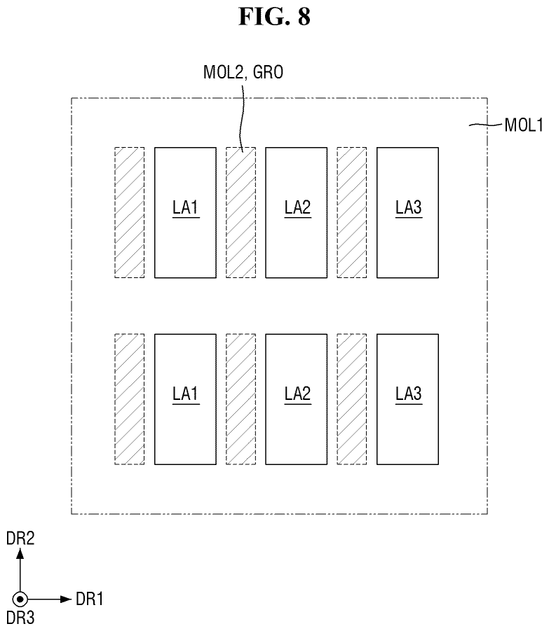

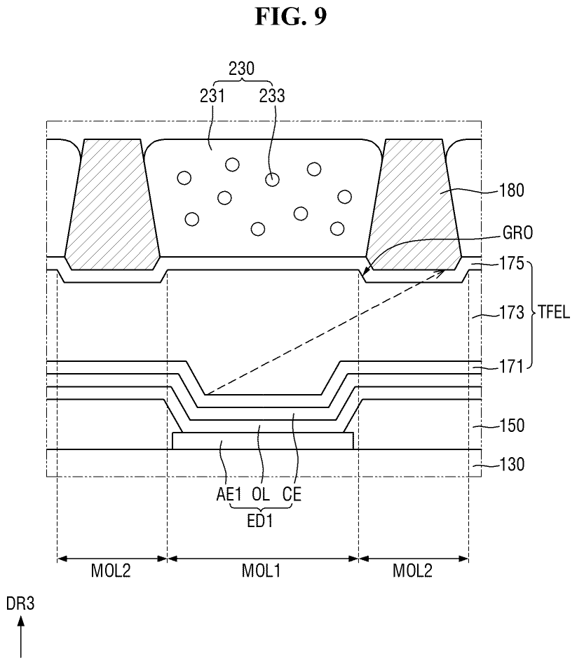

FIG. 5 is a schematic cross-sectional view schematically showing a display device according to an embodiment. FIG. 6 is a schematic cross-sectional view schematically showing a portion of a first light-emitting area of the display device according to the embodiment. FIG. 7 is a schematic plan view schematically showing an example of light-emitting areas of the display device according to the embodiment. FIG. 8 is a schematic plan view schematically showing another example of light-emitting areas of the display device according to the embodiment. FIG. 9 is a schematic cross-sectional view schematically showing a portion of a first light-emitting area of the display device according to an embodiment.

Referring to FIGS. 5 and 6, the display device 10 according to an embodiment may include a substrate SUB, an emission material layer EML, a thin-film transistor layer TFTL, a wavelength conversion layer WCL, a low-refractive layer LRL, a color filter layer CFL, and an optical functional layer LFL.

Light-emitting areas LA1, LA2 and LA3 and a non-light-emitting area NLA may be defined on the substrate SUB. In the light-emitting areas LA1, LA2 and LA3, lights generated in the light-emitting elements ED1, ED2 and ED3 may exit. In the non-light-emitting area NLA, no light may exit. According to the embodiment, a first light-emitting area LA1, a second light-emitting area LA2 and a third light-emitting area LA3 may be arranged repeatedly in this order in the first direction DR1 in the display area DPA.

The first light-emitting area LA1, the second light-emitting area LA2 and the third light-emitting area LA3 may have different widths measured in the first direction DR1. For example, the width of the first light-emitting area LA1 may be smaller than the width of the third light-emitting area LA3, and the width of the third light-emitting area LA3 may be smaller than the width of the second light-emitting area LA2. It should be understood, however, that the disclosure is not limited thereto. The first light-emitting area LA1, the second light-emitting area LA2 and the third light-emitting area LA3 may have the same width measured in the first direction DR1.

The light-emitting areas LA1, LA2 and LA3 may emit lights of different colors. According to an embodiment, the first light-emitting area LA1 may emit light of a first color, the second light-emitting area LA2 may emit light of a second color, and the third light-emitting area LA3 may emit light of a third color. According to the embodiment, the light of the first color may be blue light having a peak wavelength in the range of about 440 to about 480 nm, and the light of the second color may be red light having a peak wavelength in the range of about 610 nm to about 650 nm. The light of the third color may be green light having a peak wavelength in the range of about 510 nm to about 550 nm. It should be understood, however, that the disclosure is not limited thereto. The light of the second color may be green light and the light of the third color may be red light.

On the substrate SUB, switching elements T1, T2 and T3 may be disposed. According to an embodiment, the first switching element T1 may be located in the first light-emitting area LA1 of the substrate SUB, the second switching element T2 may be located in the second light-emitting area LA2, and the third switching element T3 may be located in the third light-emitting area LA3. It is, however, to be understood that the disclosure is not limited thereto. In other embodiments, at least one of the first switching device T1, the second switching device T2 and the third switching device T3 may be located in the non-light-emitting area NLA.

According to an embodiment, each of the first switching element T1, the second switching element T2 and the third switching element T3 may be a thin-film transistor including amorphous silicon, polysilicon, or an oxide semiconductor. Although not shown in the drawings, signal lines (for example, gate lines, data lines, power lines, etc.) for transmitting signals to the switching elements may be further disposed on the substrate SUB. The switching elements T1, T2 and T3 may include a first insulating layer 120. For example, the first insulating layer 120 may be a gate insulator or an interlayer dielectric film of a thin-film transistor. The gate insulator or the interlayer dielectric film may be made up of a single layer including one of silicon oxide (SiOₓ), silicon nitride oxide (SiOₓN_{y}), and silicon nitride (SiNₓ), or multiple layers thereof.

A second insulating layer 130 may be disposed over the first switching element T1, the second switching element T2 and the third switching element T3. According to an embodiment, the second insulating layer 130 may be a planarization film. According to an embodiment, the second insulating layer 130 may be formed as an organic film. For example, the second insulating layer 130 may include an acrylic resin, an epoxy resin, an imide resin, an ester resin, etc. According to an embodiment, the second insulating layer 130 may include a positive photoresist or a negative photoresist.

A first anode electrode AE1, a second anode electrode AE2 and a third anode electrode AE3 may be disposed on the second insulating layer 130. The first anode electrode AE1 may be disposed in the first light-emitting area LA1 and may be extended to the non-light-emitting area NLA at least partially. The second anode electrode AE2 may be disposed in the second light-emitting area LA2 and may be extended to the non-light-emitting area NLA at least partially. The third anode electrode AE3 may be disposed in the third light-emitting area LA3 and may be extended to the non-light-emitting area NLA at least partially. The first anode electrode AE1 may be connected to the first switching element T1 through the second insulating layer 130, the second anode electrode AE2 may be connected to the second switching element T2 through the second insulating layer 130, and the third anode electrode AE3 may be connected to the third switching element T3 through the second insulating layer 130.

According to an embodiment, the widths or areas of the first anode electrode AE1, the second anode electrode AE2 and the third anode electrode AE3 may be different from one another. For example, the width of the first anode electrode AE1 may be smaller than the width of the second anode electrode AE2, and the width of the third anode electrode AE3 may be smaller than the width of the second anode electrode AE2 and may be larger than the width of the first anode electrode AE1. By way of example, the area of the first anode electrode AE1 may be smaller than the area of the second anode electrode AE2, and the area of the third anode electrode AE3 may be smaller than the area of the second anode electrode AE2 and larger than the area of the first anode electrode AE1. By way of example, the area of the first anode electrode AE1 may be smaller than the area of the second anode electrode AE2, and the area of the third anode electrode AE3 may be larger than the area of the second anode electrode AE2 and the area of the first anode electrode AE1. It is, however, to be understood that the disclosure is not limited to the above-described embodiment. According to an embodiment, the widths or areas of the first anode electrode AE1, the second anode electrode AE2 and the third anode electrode AE3 may be substantially all equal.

The first anode electrode AE1, the second anode electrode AE2 and the third anode electrode AE3 may be reflective electrodes. The first anode electrode AE1, the second anode electrode AE2 and the third anode electrode AE3 may have a stack structure of a material layer having a high work function such as indium tin oxide (ITO), indium zinc oxide (IZO), zinc oxide (ZnO), indium tin zinc oxide (ITZO) and indium oxide (In₂O₃), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. A material layer having a higher work function may be disposed on a higher layer than a reflective material layer so that it may be closer to a light emitting layer OL. The first anode electrode AE1, the second anode electrode AE2 and the third anode electrode AE3 may have, but is not limited to, a multilayer structure of ITO/Mg, ITO/MgF, ITO/Ag, and ITO/Ag/ITO.

A pixel-defining layer 150 may be located on the first anode electrode AE1, the second anode electrode AE2, and the third anode electrode AE3. The pixel-defining layer 150 may include an opening exposing the first anode electrode AE1, an opening exposing the second anode electrode AE2 and an opening exposing the third anode electrode AE3, and may define the first light-emitting area LA1, the second light-emitting area LA2, the third light-emitting area LA3 and the non-light-emitting area NLA. For example, an exposed portion of the first anode electrode AE1 which is not covered by the pixel-defining layer 150 may be the first light-emitting area LA1. A portion of the second anode electrode AE2 that is not covered by the pixel-defining layer 150 but is exposed may be the second light-emitting area LA2. A portion of the third anode electrode AE3 that is not covered by the pixel-defining layer 150 but is exposed may be the third light-emitting area LA3. The other portions where the pixel-defining layer 150 is located may be the non-light-emitting area NLA.

The pixel-defining layer 150 may include an organic insulating material such as a polyacrylate resin, an epoxy resin, a phenolic resin, a polyamide resin, a polyimide resin, an unsaturated polyester resin, a polyphenylene resin, a poly phenylene sulfide resin, and benzocyclobutene (BCB).

According to an embodiment, the pixel-defining layer 150 may overlap a bank 180 of the wavelength conversion layer WCL to be described later. The light emitting layer OL may be disposed on the first anode electrode AE1, the second anode electrode AE2, and the third anode electrode AE3. In an embodiment where the display device 10 is an organic light-emitting display device, the light emitting layer OL may include an organic layer containing an organic material. The organic layer may include an organic, emissive layer and may further include at least one of: a hole injection layer, a hole transport layer, an electronic transport layer and an electron injection layer as an auxiliary layer in some implementations in order to facilitate light emission.

According to an embodiment, the light emitting layer OL may have a tandem structure including organic emissive layers overlapping one another in the thickness direction and a charge generation layer disposed therebetween. The organic emissive layer overlapping one another may emit either light of the same wavelength or lights of different wavelengths. For example, the overlapping organic emissive layers may include an organic emissive layer that emits light in a green wavelength and an organic emissive layer that emits light in a blue wavelength. According to an embodiment, the overlapping organic emissive layers may include an organic emissive layer that emits light in a red wavelength, an organic emissive layer that emits light in a green wavelength, and an organic emissive layer that emits light in a blue wavelength.

According to an embodiment, the light emitting layer OL may have the shape of a continuous film disposed across the light-emitting areas LA1, LA2 and LA3 and the non-light-emitting area NLA. In this instance, the wavelengths of lights emitted from the light emitting layer OL may be the same. For example, the light emitting layer OL may emit blue light, light of white wavelength or ultraviolet light from the light-emitting areas LA1, LA2 and LA3.

A cathode electrode CE may be disposed on the light emitting layer OL. According to an embodiment, the cathode electrode CE may be semi-transmissive or transmissive. If the cathode electrode CE is transflective, it may include Ag, Mg, Cu, Al, Pt, Pd, Au, Ni, Nd, Ir, Cr, Li, Ca, LiF/Ca, LiF/Al, Mo, Time or a compound or a mixture thereof, for example, a mixture of Ag and Mg. Further, if the thickness of the cathode electrode CE ranges from several tens to several hundred angstroms, the cathode electrode CE may be transflective.

In case that the cathode electrode CE is transmissive, the cathode electrode CE may include a transparent conductive oxide (TCO). For example, the cathode electrode CE may be formed of tungsten oxide (WₓO_{y}), titanium oxide (TiO₂), indium tin oxide (ITO), indium zinc oxide (IZO), zinc oxide (ZnO), indium tin zinc oxide MgO (magnesium oxide), etc.

The first anode electrode AE1, the light emitting layer OL and the cathode electrode CE may form a first light-emitting element ED1, the second anode electrode AE2, the light emitting layer OL and the cathode electrode CE may form a second light-emitting element ED2, and the third anode electrode AE3, the light emitting layer OL and the cathode electrode CE may form a third light-emitting element ED3. Each of the first light-emitting element ED1, the second light-emitting element ED2 and the third light-emitting element ED3 may emit a source light. The source light may be provided to the wavelength conversion layer WCL. For example, the source light may be, but is not limited to, blue light. It may be white light, or ultraviolet light. The first light-emitting element ED1, the second light-emitting element ED2 and the third light-emitting element ED3 may be organic light-emitting diodes.

The thin-film encapsulation layer TFEL may be disposed on the cathode electrode CE. The thin-film encapsulation layer TFEL may be located commonly across the first light-emitting area LA1, the second light-emitting area LA2, the third light-emitting area LA3, and the non-light-emitting area NLA. According to an embodiment, the thin-film encapsulation layer TFEL may directly cover the cathode electrode CE.

According to an embodiment, the thin-film encapsulation layer TFEL may include a first encapsulation layer 171, a second encapsulation layer 173 and a third encapsulation layer 175 sequentially stacked each other on the cathode electrode CE.

The first encapsulation layer 171 may be disposed on the cathode electrode CE. The first encapsulation layer 171 may directly cover the cathode electrode CE of the emission material layer EML to thereby prevent permeation of moisture or foreign substances into the emission material layer EML. The first encapsulation layer 171 may include an inorganic material. For example, the first encapsulation layer 171 may include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. It is, however, to be understood that the disclosure is not limited thereto.

The second encapsulation layer 173 may be disposed on the first encapsulation layer 171. The second encapsulation layer 173 can prevent foreign substances or particles from being seated on the first encapsulation layer 171 and deteriorating the encapsulation performance. For example, the second encapsulation layer 173 may be formed to be thick enough to cover foreign substances or particles, thereby preventing deterioration of encapsulation performance.

The second encapsulation layer 173 may include an organic material. For example, the second encapsulation layer 173 may include an acrylic resin, a methacrylate resin, polyisoprene, a vinyl resin, an epoxy resin, a urethane resin, a cellulose resin, a perylene resin, etc. It is, however, to be understood that the disclosure is not limited thereto.

According to an embodiment, the second encapsulation layer 173 may include first regions MOL1 and second regions MOL2.

The first regions MOL1 may overlap the light-emitting areas LA1, LA2 and LA3, and may be thicker portions of the second encapsulation layer 173. In the first regions MOL1, light emitted from the light-emitting elements ED1, ED2 and ED3 may substantially exit to the wavelength conversion layer WCL. Therefore, the first regions MOL1 may be located to cover at least the light-emitting areas LA1, LA2 and LA3. At least a portion of the first regions MOL1 may overlap the non-light-emitting area NLA. The first regions MOL1 may not overlap the bank 180 of the wavelength conversion layer WCL, which will be described later.

The second regions MOL2 may not overlap the light-emitting areas LA1, LA2 and LA3, and may be thinner portions of the second encapsulation layer 173 than the first regions MOL1. The second regions MOL2 may be located between the light-emitting areas LA1, LA2 and LA3. The second regions MOL2 may overlap the non-light-emitting area NLA. According to an embodiment, the second regions MOL2 may completely overlap the non-light-emitting area NLA. The second regions MOL2 may overlap the bank 180 of the wavelength conversion layer WCL, which will be described later.

The second encapsulation layer 173 may include grooves GRO formed in its surface. In the second regions MOL2, the grooves GRO may be formed in the second encapsulation layer 173. The grooves GRO may have a concave shape in the thickness direction from the surface of the second encapsulation layer 173. The second regions MOL2 may have a thickness smaller than the first regions MOL1 due to the grooves GRO. The grooves GRO may overlap the second regions MOL2. According to an embodiment, the grooves GRO may completely overlap the second regions MOL2. The grooves GRO may have a selectable depth. The depth of the grooves GRO may be a vertical distance from the surface of the first regions MOL1 to the surface of the second regions MOL2.

The first regions MOL1 may have a first thickness TT1, and the second regions MOL2 may have a second thickness TT2. The first thickness TT1 of the first regions MOL1 may be greater than the second thickness TT2 of the second regions MOL2. For example, the first thickness TT1 may range from about 1 μm to about 10 μm, and the second thickness TT2 may range from about 50% to about 90% of the first thickness TT1. With the first thickness TT1 or the second thickness TT2 in the above range, it is possible to completely cover a foreign substance placed on the first encapsulation layer 171 to improve the encapsulation performance.

As shown in FIG. 7, the first regions MOL1 of the second encapsulation layer 173 may have an area larger than the light-emitting areas LA1, LA2 and LA3. The first regions MOL1 may completely cover the light-emitting areas LA1, LA2 and LA3. The first regions MOL1 may be spaced apart from one another.

The second regions MOL2 may not overlap the light-emitting areas LA1, LA2 and LA3, and may be located in other regions than the first regions MOL1. For example, the first regions MOL1 may be spaced apart from one another similar to the shape of the light-emitting area LA1, LA2 and LA3, and may be arranged in a dot pattern when viewed from the top. The second regions MOL2 may surround the first regions MOL1. The grooves GRO formed in the second regions MOL2 may be arranged in the same manner as the second regions MOL2.

Referring to FIG. 8, according to an embodiment, the first regions MOL1 may be located to cover the light-emitting areas LA1, LA2 and LA3, and may have a matrix shape when viewed from the top. The second regions MOL2 may not overlap any of the light-emitting areas LA1, LA2 and LA3. The second regions MOL2 may be arranged in a dot pattern when viewed from the top, and the grooves GRO formed in the second regions MOL2 may be arranged in the same material manner as the second regions MOL2 when viewed from the top.

The second regions MOL2 may be spaced apart from one another and may be located between the light-emitting areas LA1, LA2 and LA3 that emit lights of different colors. For example, the second regions MOL2 may be located between the first light-emitting area LA1 and the second light-emitting area LA2, between the second light-emitting area LA2 and the third light-emitting area LA3, and between the third light-emitting area LA3 and the first light-emitting area LA1. The second regions MOL2 may not be located between the light-emitting areas LA1, LA2 and LA3 that emit lights of the same color. For example, the second region MOL2 may not be located between the first light-emitting areas LA1, between the second light-emitting areas LA2 or between the third light-emitting areas LA3. It should be understood, however, that the disclosure is not limited thereto. The second region MOL2 may be located between the light-emitting areas LA1, LA2 and LA3 that emit lights of the same color.

According to this embodiment, the second regions MOL2 of the second encapsulation layer 173 are located in the non-light-emitting area NLA and the bank 180 of the wavelength conversion layer WCL is formed on the second regions MOL2, which will be described later. In this manner, it is possible to prevent color mixing of lights exiting from the light-emitting areas LA1, LA2 and LA3 to adjacent light-emitting areas LA1, LA2 and LA3.

As shown in FIG. 9, while most of the lights emitted from the first light-emitting element ED1 exit toward the light-transmitting pattern 230 of the wavelength conversion layer WCL, some of the lights may exit to an adjacent light-emitting area. By forming the second regions MOL2 having the grooves GRO in the second encapsulation layer 173, the bank 180 may be extended further toward the pixel-defining layer 150. Since the bank 180 contains a light blocking/absorbing material, it can prevent color mixing by blocking or absorbing light exiting to adjacent light-emitting areas. As a result, it is possible to improve the color gamut of the display device 10.

The third encapsulation layer 175 may be disposed on the second encapsulation layer 173. The third encapsulation layer 175 may be disposed to cover both the first region MOL1 and the second region MOL2 of the second encapsulation layer 173, to prevent permeation of moisture or foreign substances into the second encapsulation layer 173. The third encapsulation layer 175 may include an inorganic material. For example, the third encapsulation layer 175 may include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. It is, however, to be understood that the disclosure is not limited thereto.

It is to be noted that the structure of the thin-film encapsulation layer TFEL is not limited to the above example. The stack structure of the thin-film encapsulation layer TFEL may be altered in a variety of ways.

Referring again to FIGS. 5 and 6, the wavelength conversion layer WCL may be disposed on the thin-film encapsulation layer TFEL. The wavelength conversion layer WCL may include a bank 180, a light-transmitting pattern 230, a first wavelength conversion pattern 240, a second wavelength conversion pattern 250, and a capping layer 300.

The bank 180 may be disposed on the thin-film encapsulation layer TFEL. The bank 180 may partition the light-emitting areas LA1, LA2 and LA3 and the non-light-emitting area NLA. The bank 180 may be disposed in the non-light-emitting area NLA and can block the transmission of light. By way of example, the bank 180 may be disposed between the light-transmitting pattern 230 and the first wavelength conversion pattern 240, between the first wavelength conversion pattern 240 and the second wavelength conversion pattern 250, and between the second wavelength conversion pattern 250 and the light-transmitting pattern 230, to prevent color mixing between adjacent light-emitting areas.

The bank 180 may not overlap the first regions MOL1 of the second encapsulation layer 173 of the thin-film encapsulation layer TFEL and may overlap the second regions MOL2. For example, the bank 180 may be disposed in the grooves GRO of the second regions MOL2. Accordingly, it is possible to block transmission of lights exiting from the light-emitting area LA1, LA2 and LA3 toward adjacent light-emitting areas. In this manner, it is possible to prevent color mixing between adjacent light-emitting areas.

The bank 180 may include an organic light-blocking material and may be formed via coating and exposure processes of the organic light-blocking material, or by inkjet printing. For example, the bank 180 may include an organic material and a dye or pigment that can block light mixed in the organic material. The organic material may include an acrylic resin, a methacrylate-based resin, polyisoprene, a vinyl resin, an epoxy resin, a urethane resin, a cellulose resin and a perylene resin. The dye or pigment may include carbon black, etc.

The light-transmitting pattern 230 may be disposed on the thin-film encapsulation layer TFEL. The light-transmitting pattern 230 may overlap the first light-emitting area LA1. The light-transmitting pattern 230 may transmit incident light. If the source light provided from the first light-emitting element ED1 is blue light, the blue source light may pass through the light-transmitting pattern 230.

According to an embodiment, the light-transmitting pattern 230 may include a first base resin 231 and may further include first scatterers 233 dispersed in the first base resin 231.

The first base resin 231 may be made of a material having a high light transmittance. According to an embodiment, the first base resin 231 may be made of an organic material. For example, the first base resin 231 may include an organic material such as an epoxy resin, an acrylic resin, a cardo resin, or an imide resin.

The first scatterers 233 may have a refractive index different from that of the first base resin 231 and may form an optical interface with the first base resin 231. For example, the first scatterers 233 may be light scattering particles. The material of the first scatterers 233 is not particularly limited as long as they can scatter at least a portion of the transmitted light. For example, the first scatterers 233 may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc. The first scatterers 233 can scatter light in random directions regardless of the direction in which the incident light is coming, without substantially changing the wavelength of the light transmitted through the light-transmitting pattern 230.

According to an embodiment, the light-transmitting pattern 230 may be formed by applying a photosensitive material, exposing it to light, and developing it. It should be understood, however, that the disclosure is not limited thereto. The light-transmitting pattern 230, the first wavelength conversion pattern 240 and the second wavelength conversion pattern 250 may be formed by inkjet printing.

The first wavelength conversion pattern 240 and the second wavelength conversion pattern 250 may be disposed on the thin-film encapsulation layer TFEL.

The first wavelength conversion pattern 240 may be located on the thin-film encapsulation layer TFEL in the second light-emitting area LA2. The first wavelength conversion pattern 240 may convert or shift the peak wavelength of the incident light into light of another peak wavelength and emit the light. According to an embodiment, the first wavelength conversion pattern 240 may convert the source light provided from the second light-emitting element ED2 into red light having a peak wavelength in the range of about 610 nm to about 650 nm to output it.

The first wavelength conversion pattern 240 may include a second base resin 241 and first wavelength shifters 245 dispersed in the second base resin 241, and may further include second scatterers 243 dispersed in the second base resin 241.

The second base resin 241 may be made of a material having a high light transmittance. According to an embodiment, the second base resin 241 may be made of an organic material. The second base resin 241 may be made of the same material as the first base resin 231, or may include at least one of the materials listed above as the examples of the constituent materials of the first base resin 231.

The first wavelength shifters 245 may convert or shift the peak wavelength of the incident light to another peak wavelength. According to an embodiment, the first wavelength shifters 245 may convert the source light provided from the second light-emitting element ED2, for example, the light of the first color which is blue light into red light having a single peak wavelength in the range of about 610 nm to about 650 nm to output it.

Examples of the first wavelength shifters 245 may include quantum dots, quantum rods or phosphors. For example, quantum dots may be particulate matter that emits a color as electrons transition from the conduction band to the valence band.

The quantum dots may be semiconductor nanocrystalline material. The quantum dots have a specific band gap depending on their compositions and size, and can absorb light and emit light having an intrinsic wavelength. Examples of the semiconductor nanocrystals of the quantum dots may include Group IV nanocrystals, Groups II-VI compound nanocrystals, Groups III-V compound nanocrystals, Groups IV-VI nanocrystals, or combinations thereof.

The group II-VI compounds may be selected from the group consisting of: binary compounds selected from the group consisting of CdSe, CdTe, ZnS, ZnSe, ZnTe, ZnO, HgS, HgSe, HgTe, MgSe, MgS and a mixture thereof; ternary compounds selected from the group consisting of InZnP, AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof.

The group III-V compounds may be selected from the group consisting of: binary compounds selected from the group consisting of GaN, GaP, GaAs, GaSb, AlN, AIP, AlAs, AlSb, InN, InP, InAs, InSb and a mixture thereof; ternary compounds selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and a mixture thereof; and quaternary compounds selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof.

The group IV-VI compounds may be selected from the group consisting of: binary compounds selected from the group consisting of SnS, SnSe, SnTe, PbS, PbSe, PbTe and a mixture thereof; ternary compounds selected from the group consisting of SnSeS, SnSeTe, SnSTe, PbSeS, PbSeTe, PbSTe, SnPbS, SnPbSe, SnPbTe and a mixture thereof; and quaternary compounds selected from the group consisting of SnPbSSe, SnPbSeTe, SnPbSTe and a mixture thereof. The group IV elements may be selected from the group consisting of Si, Ge and a mixture thereof. The group IV compounds may be binary compounds selected from the group consisting of SiC, SiGe and a mixture thereof.

The binary compounds, the ternary compounds or the quaternary compounds may be present in the particles at a uniform concentration, or may be present in the same particles at partially different concentrations. They may have a core/shell structure in which one quantum dot surrounds another quantum dot. At the interface between the core and the shell, the gradient of the concentrate of atoms in the shell may decrease toward the center.

According to an embodiment, the quantum dots may have a core-shell structure including a core comprising the nanocrystals and a shell surrounding the core. The shell of the quantum-dots may serve as a protective layer for maintaining the semiconductor properties by preventing chemical denaturation of the core and/or as a charging layer for imparting electrophoretic properties to the quantum dots. The shell may be either a single layer or multiple layers. Examples of the shell of the quantum dot may include an oxide of a metal or a non-metal, a semiconductor compound, a combination thereof, etc.

For example, examples of the metal or non-metal oxide may include, but is not limited to, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO or ternary compounds such as MgAl₂O₄, CoFe₂O₄, NiFe₂O₄ and CoMn₂O₄.

Examples of the semiconductor compound may include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

The light output from the first wavelength shifters 245 may have a full width at half maximum (FWHM) of the emission wavelength spectrum of about 45 nm or less, about 40 nm or less, or about 30 nm or less. Accordingly, the color purity and color gamut of the colors displayed by the display device 10 can be further improved. The light output from the first wavelength shifters 245 may travel in different directions regardless of the incidence direction of the incident light. In this manner, the side visibility of the second color displayed in the second light-emitting area LA2 can be improved.

Some of the source lights provided from the second light-emitting element ED2 may not be converted into red light by the first wavelength shifters 245. However, the lights that are not converted into red light may be blocked by the color filter layer CFL disposed thereabove. On the other hand, red light converted by the first wavelength conversion pattern 240 passes through the color filter layer CFL and exit to the outside.

The second scatterers 243 may have a refractive index different from that of the second base resin 241 and may form an optical interface with the second base resin 241. For example, the second scatterers 243 may be light scattering particles. The second scatterers 243 are substantially identical to the first scatterers 233 described above; and, therefore, the redundant description will be omitted.

The second wavelength conversion pattern 250 may be located on the thin-film encapsulation layer TFEL in the third light-emitting area LA3. The second wavelength conversion pattern 250 may convert or shift the peak wavelength of the incident light into light of another peak wavelength to emit the light. According to an embodiment, the second wavelength conversion pattern 250 may convert the source light provided from the third light-emitting element ED3 into green light in the range of about 510 nm to about 550 nm to output it.

The second wavelength conversion pattern 250 may include a third base resin 251 and second wavelength shifters 255 dispersed in the third base resin 251, and may further include third scatterers 253 dispersed in the third base resin 251.

The third base resin 251 may be made of a material having a high light transmittance. According to an embodiment, the third base resin 251 may be made of an organic material. The third base resin 251 may be made of the same material as the first base resin 231, or may include at least one of the materials listed above as the examples of the constituent materials of the first base resin 231.

The second wavelength shifters 255 may convert or shift the peak wavelength of the incident light to another peak wavelength. According to an embodiment, the second wavelength shifters 255 may convert the source light having a peak wavelength in the range of about 440 nm to about 480 nm, for example, blue light into green light having a peak wavelength in the range of about 510 nm to about 550 nm.

Examples of the second wavelength shifters 255 may include quantum dots, quantum rods or phosphors. The second wavelength shifters 255 are substantially identical to the first wavelength shifters 245; and, therefore, the redundant description will be omitted. According to an embodiment, the first wavelength shifters 245 and the second wavelength shifters 255 may all be made up of quantum dots. In such case, the particle size of the quantum dots forming the first wavelength shifters 245 may be greater than the particle size of the quantum dots forming the second wavelength shifters 255.

The third scatterers 253 may have a refractive index different from that of the third base resin 251 and may form an optical interface with the third base resin 251. For example, the third scatterers 253 may be light scattering particles. The third scatterers 253 are substantially identical to the second scatterers 243 described above; and, therefore, the redundant description will be omitted.

The source light output from the third light-emitting element ED3 may be provided to the second wavelength conversion pattern 250. The second wavelength shifters 255 may convert the source light provided from the third light-emitting element ED3 into green light having a peak wavelength in the range of about 510 nm to about 550 nm to output it.

Some of the source lights may not be converted into green light by the second wavelength shifters 255 and may pass through the second wavelength conversion pattern 250. However, light that is not converted to green light may be blocked by the color filter layer CFL. On the other hand, green light converted by the second wavelength conversion pattern 250 passes through the color filter layer CFL and exit to the outside.

The capping layer 300 may be disposed on the bank 180, the light-transmitting pattern 230, the first wavelength conversion pattern 240 and the second wavelength conversion pattern 250 to cover them. Thus, it is possible to prevent impurities such as moisture and air from permeating from the outside to damage or contaminate the bank 180, the light-transmitting pattern 230, the first wavelength conversion pattern 240 and the second wavelength conversion pattern 250.

The capping layer 300 may be made of an inorganic material. For example, the capping layer 300 may be made of a material including silicon nitride, aluminum nitride, zirconium nitride, titanium nitride, hafnium nitride, tantalum nitride, silicon oxide, aluminum oxide, titanium oxide, tin oxide, silicon oxynitride, etc.

The low-refractive layer LRL may be disposed on the wavelength conversion layer WCL. For example, the low-refractive layer LRL may be disposed directly on the wavelength conversion layer WCL and the capping layer 300. The low-refractive layer LRL may be disposed entirely in the display area DPA (see FIG. 1) of the display device 10. For example, the low-refractive layer LRL may be disposed on the light-emitting areas LA1, LA2 and LA3 and the non-light-emitting area NLA in the display area. The low-refractive layer 320 may have a relatively lower refractive index than the light-transmitting pattern 230, the first wavelength conversion pattern 240, the second wavelength conversion pattern 250 and the capping layer 300. In the low-refractive layer 320, lights from below may be refracted toward the top due to the difference in refractive index so that the emission efficiency can be improved.

The low-refractive layer LRL may include air pores dispersed in a transparent resin. The resin may include one or more selected from the group consisting of: acryl, polysiloxane, polyurethane, polyurethane acrylate, polyimide, polymethylsilsesquioxane (PMSSQ), and poly(methyl methacrylate) (PMMA). The air pores are holes containing air, which can be randomly distributed in the resin.

The low-refractive layer LRL may further include hollow particles. The hollow particles may include one or more selected from the group consisting of: silica (SiO₂), magnesium fluoride (MgF₂), and iron oxide (Fe₃O₄). For example, the hollow particles may include a shell made of one or more of the above materials and a hollow in the shell. According to an embodiment, the diameter of the hollow particles may range from, but is not limited to, about 20 nm to about 200 nm.

The color filter layer CFL may be disposed on the low-refractive layer LRL. The color filter layer CFL may include a first color filter 350, a second color filter 360, and a third color filter 370. It may include a first color pattern 355, a second color pattern 365, and a third color pattern 375.

The first color filter 350 may overlap the third light-emitting area EA3. The first color filter 350 may be disposed to overlap the third light-emitting element ED3 and the second wavelength conversion pattern 250. The first color pattern 355 may be spaced apart from the first color filter 350 and may be overlapped the non-light-emitting area NLA. The first color filter 350 may be in direct contact with the low-refractive layer LRL.

The first color filter 350 and the first color pattern 355 may selectively transmit light of the third color (for example, green light) and may block or absorb light of the first color (for example, blue light) and light of the second color (for example, red light). According to the embodiment, the first color filter 350 may be a green color filter and may include a green colorant such as a green dye and a green pigment. As used herein, the colorant encompasses a dye as well as a pigment.

The second color filter 360 may overlap the second light-emitting area LA2. The second color filter 360 may overlap the second light-emitting element ED2 and the first wavelength conversion pattern 240. According to the embodiment, one side or a side of the second color filter 360 may be disposed in the non-light-emitting area NLA and overlap the adjacent first color filter 350. The opposite side of the second color filter 360 may be disposed in the non-light-emitting area NLA and overlap the first color pattern 355. The second color pattern 365 may be spaced apart from the second color filter 360 and may overlap the non-light-emitting area NLA. The second color pattern 365 may overlap the first color filter 350 in the non-light-emitting area NLA. The second color filter 360 may be in direct contact with the low-refractive layer LRL.

The second color filter 360 and the second color pattern 365 may selectively transmit light of the second color (for example, red light) and may block and absorb light of the first color (for example, blue light) and light of the third color (for example, green light). For example, the second color filter 360 may be a red color filter and may include a red colorant such as a red dye and a red pigment.

The third color filter 370 may overlap the first light-emitting area LA1. The third color filter 370 may overlap the first light-emitting element ED1 and the light-transmitting pattern 230. According to the embodiment, one side or a side of the third color filter 370 may be disposed in the non-light-emitting area NLA and overlap the adjacent second color filter 360. The opposite side of the third color filter 370 may be disposed in the non-light-emitting area NLA and overlap the adjacent first color filter 350 and the second color pattern 365. The third color pattern 375 may be spaced apart from the third color filter 370 and may be overlapped the non-light-emitting area NLA. The third color pattern 375 may overlap the second color filter 360 in the non-light-emitting area NLA. The third color filter 370 and the third color pattern 375 may be in direct contact with the low-refractive layer LRL.

The third color filter 370 may selectively transmit light of the first color (for example, blue light) and may block and absorb light of the second color (for example, red light) and light of the third color (for example, green light). For example, the third color filter 370 may be a blue color filter and may include a blue colorant such as a blue dye and a blue pigment.

As described above, the first to third color filters 350, 360 and 370 and the first to third color patterns 355, 365 and 375 overlap each other in the non-light-emitting area NLA to block or absorb light. For example, in the non-light-emitting area NLA disposed on one side or a side of the second light-emitting area LA2, the first color pattern 355, the second color filter 360 and the third color filter 370 overlap one another, and in the non-light-emitting area NLA disposed on the opposite side of the second light-emitting area LA2, the first color filter 350, the second color filter 360 and the third color filter 370 may overlap one another.

An overcoat layer 380 may be disposed on the first to third color filters 350, 360 and 370 and the first to third color patterns 355, 365 and 375. The overcoat layer 380 may provide a flat surface over the color filter layer CFL so that the optical function layer LFL can be more reliably attached, which will be described later.

The overcoat layer 380 may be made of an organic material. For example, the overcoat layer 380 may include an acrylic resin, a methacrylate resin, polyisoprene, an imide resin, a vinyl resin, an epoxy resin, a urethane resin, a cellulose resin, a perylene resin, etc.

The optical functional layer LFL may be disposed on the color filter layer CFL. For example, the optical function layer LFL may be disposed directly on the overcoat layer 380 of the color filter layer CFL. The optical functional layer LFL may be an anti-reflection layer that prevents reflection of external light. The optical functional layer LFL may be attached in the form of a film or formed by coating. It should be understood, however, that the disclosure is not limited thereto. An anti-fingerprint layer or the like may be disposed.

As described above, according to this embodiment, the second regions MOL2 having the grooves GRO formed therein is formed in the second encapsulation layer 173 of the thin-film encapsulation layer TFEL, and the bank 180 is formed in the grooves GRO in the display device 10, so that it is possible to block light exiting from the light-emitting areas LA1, LA2 and LA3 to adjacent light-emitting areas. Therefore, it is possible to prevent color mixing between the light-emitting areas of the display device to improve the color gamut.

Hereinafter, other embodiments will be described with reference to the other drawings.

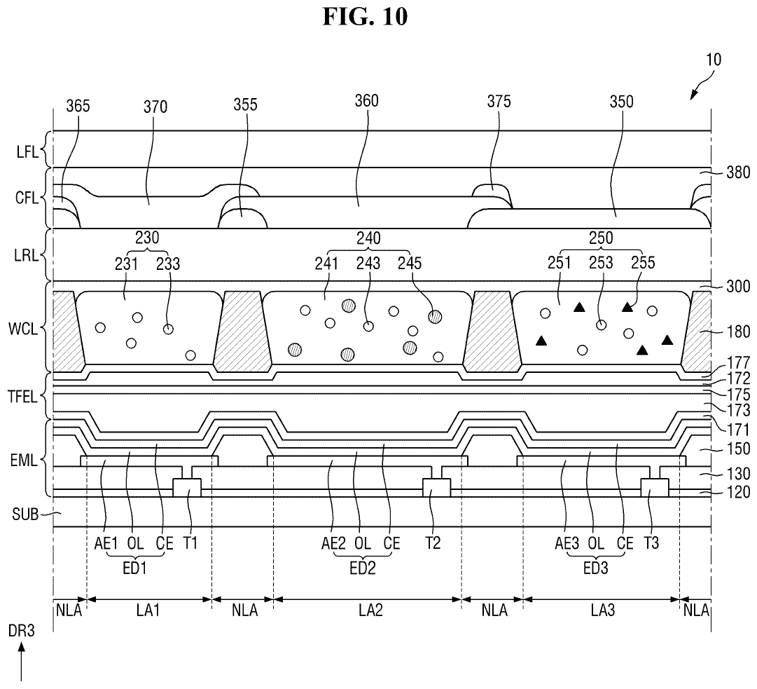

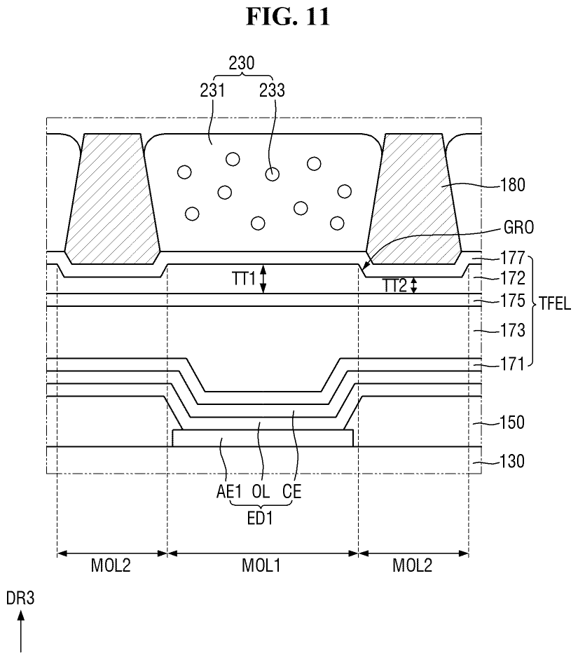

FIG. 10 is a schematic cross-sectional view schematically showing a display device according to an embodiment. FIG. 11 is a schematic cross-sectional view schematically showing a portion of the first light-emitting area of FIG. 10. FIGS. 10 and 11 show areas corresponding to FIGS. 5 and 6 described above, respectively.

The embodiment of FIGS. 10 and 11 is substantially identical to the above-described embodiment of FIGS. 5 to 9 except that a thin-film encapsulation layer TFEL further may include a fourth encapsulation layer 172 and a fifth encapsulation layer 177; and, therefore, the redundant descriptions will be omitted.

The thin-film encapsulation layer TFEL of the display device 10 according to the embodiment may include a first encapsulation layer 171, a second encapsulation layer 173, a third encapsulation layer 175, a fourth encapsulation layer 172 and a fifth encapsulation layer 177.

The first encapsulation layer 171 may be disposed on the emission material layer EML, and the second encapsulation layer 173 may be disposed on the first encapsulation layer 171. Unlike the above-described embodiment, the second encapsulation layer 173 may provide a flat upper surface over the underlying elements having different heights. For example, the height of the second encapsulation layer 173 measured from the substrate SUB may be equal in the light-emitting areas LA1, LA2 and LA3 and the non-light-emitting e area NLA. The third encapsulation layer 175 may be disposed on the second encapsulation layer 173. The third encapsulation layer 175 may be flat due to the second encapsulation layer 173 having the flat upper surface.

Since the first encapsulation layer 171, the second encapsulation layer 173 and the third encapsulation layer 175 may be made of the same materials as the above-described embodiment; and, therefore, the redundant descriptions will be omitted.

The fourth encapsulation layer 172 may be disposed on the third encapsulation layer 175, and the fifth encapsulation layer 177 may be disposed on the fourth encapsulation layer 172.

The fourth encapsulation layer 172 may include first regions MOL1 and second regions MOL2.

The first regions MOL1 may overlap the light-emitting areas LA1, LA2 and LA3, and may be thicker portions of the fourth encapsulation layer 172. In the fourth encapsulation layer 172, light emitted from the light-emitting elements ED1, ED2 and ED3 may substantially exit to the wavelength conversion layer WCL. Therefore, the first regions MOL1 may be located to cover at least the light-emitting areas LA1, LA2 and LA3. At least a portion of the first regions MOL1 may overlap the non-light-emitting area NLA. The first regions MOL1 may not overlap the bank 180 of the wavelength conversion layer WCL.

The second regions MOL2 may not overlap the light-emitting areas LA1, LA2 and LA3, and may be thinner portions of the fourth encapsulation layer 172 than the first regions MOL1. The second regions MOL2 may be located between the light-emitting areas LA1, LA2 and LA3. The second regions MOL2 may overlap the non-light-emitting area NLA. According to an embodiment, the second regions MOL2 may completely overlap the non-light-emitting area NLA. The second regions MOL2 may overlap the bank 180 of the wavelength conversion layer WCL.

In the second regions MOL2, the grooves GRO may be formed in the fourth encapsulation layer 172. The grooves GRO may have a concave shape in the thickness direction from the surface of the fourth encapsulation layer 172. The second regions MOL2 may have a thickness smaller than the first regions MOL1 due to the grooves GRO. The grooves GRO may overlap the second regions MOL2. According to an embodiment, the grooves GRO may completely overlap the second regions MOL2. The grooves GRO may have a selectable depth. The depth of the grooves GRO may be a vertical distance from the surface of the first regions MOL1 to the surface of the second regions MOL2.

The first regions MOL1 may have a first thickness TT1, and the second regions MOL2 may have a second thickness TT2. The first thickness TT1 of the first regions MOL1 may be greater than the second thickness TT2 of the second regions MOL2. For example, the first thickness TT1 may range from about 1 μm to about 5 μm, and the second thickness TT2 may range from about 50% to about 90% of the first thickness TT1.

The layouts of the first regions MOL1, the second regions MOL2 and the grooves GRO of the fourth encapsulation layer 172 are identical to that shown in FIGS. 7 and 8; and, therefore, the redundant descriptions will be omitted.

According to this embodiment, the second regions MOL2 of the fourth encapsulation layer 172 are located in the non-light-emitting area NLA and the bank 180 of the wavelength conversion layer WCL is formed on the second regions MOL2. In this manner, it is possible to prevent color mixing of lights exiting from the light-emitting areas LA1, LA2 and LA3 to adjacent light-emitting areas LA1, LA2 and LA3.

For example, according to this embodiment, the third encapsulation layer 175 may be disposed between the second encapsulation layer 173 and the fourth encapsulation layer 172. During the process of fabricating the thin-film encapsulation layer TFEL, if the patterning process of forming the grooves GRO in the second encapsulation layer 173 is not possible as shown in FIG. 5 above, the third encapsulation layer 175 may be formed on the second encapsulation layer 173 to achieve the encapsulation performance. Subsequently, the fourth encapsulation layer 172 may be additionally formed to perform a patterning process of forming grooves GRO. Accordingly, there are advantages that the reliability of the thin-film encapsulation film TFEL can be ensured and color mixing can be prevented.

The fifth encapsulation layer 177 may be disposed on the fourth encapsulation layer 172. The fifth encapsulation layer 177 may be disposed to cover both the first region MOL1 and the second region MOL2 of the fourth encapsulation layer 172, to prevent permeation of moisture or foreign substances into the fourth encapsulation layer 172. The fifth encapsulation layer 177 may include the same material as the first and third encapsulation layers 171 and 175 described above.

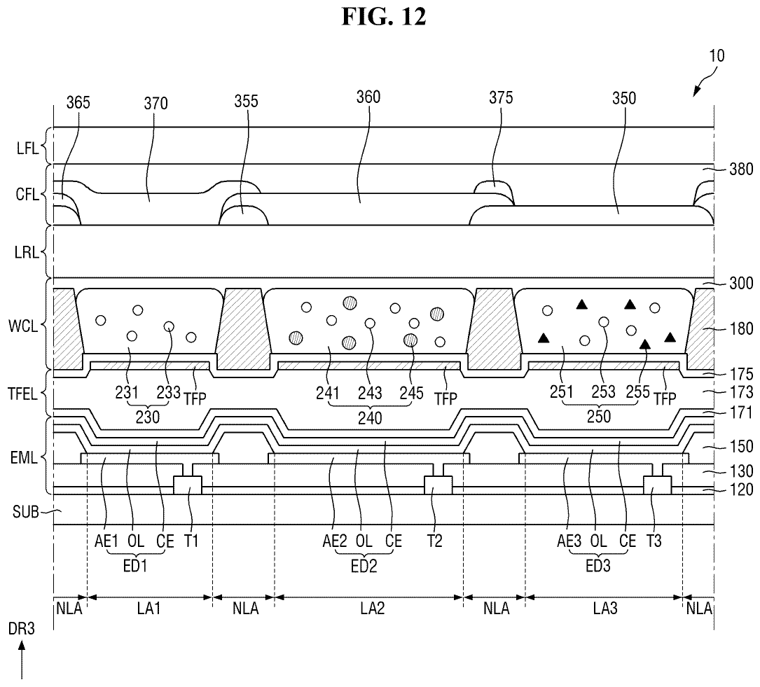

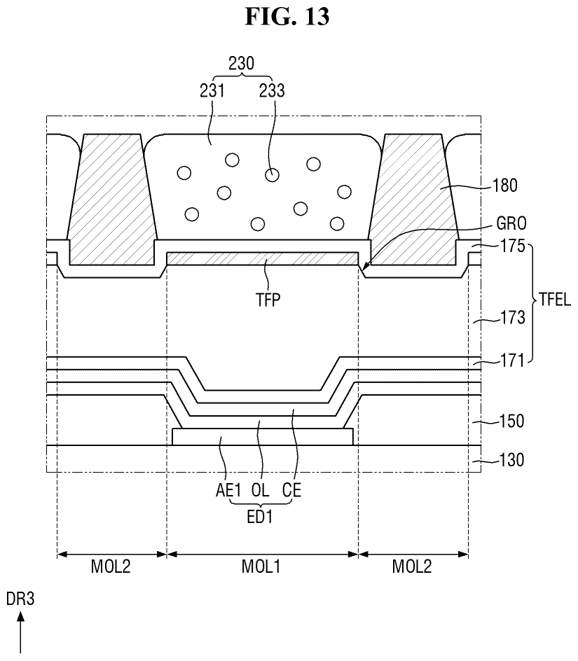

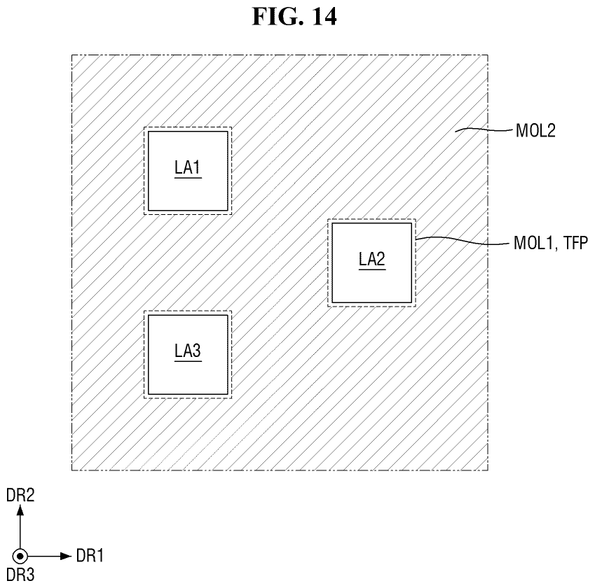

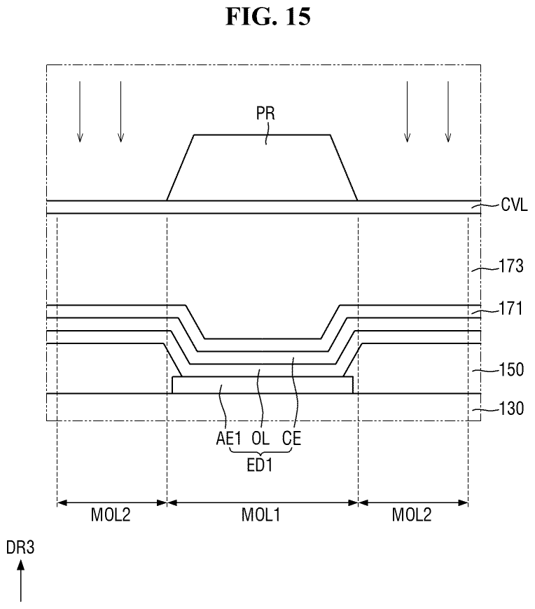

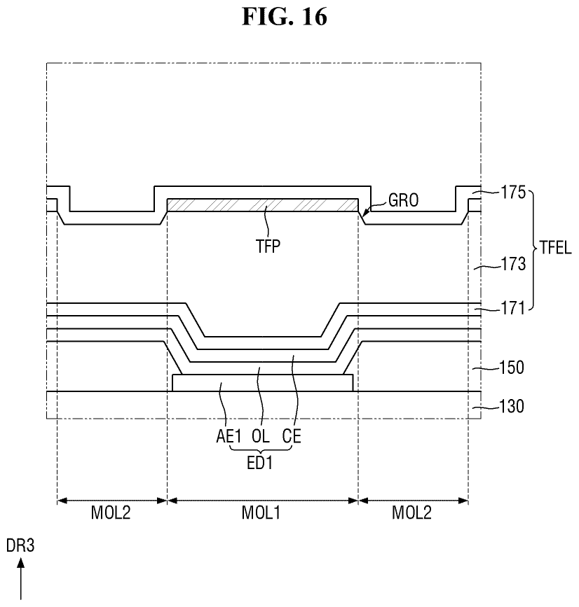

FIG. 12 is a schematic cross-sectional view schematically showing a display device according to an embodiment. FIG. 13 is a schematic cross-sectional view schematically showing a portion of the first light-emitting area of FIG. 12. FIG. 14 is a schematic plan view showing a layout of light-emitting areas of a display device according to an embodiment. FIGS. 15 and 16 are schematic cross-sectional views showing processing steps of a method of fabricating a thin-film encapsulation layer in a display device according to an embodiment.

The embodiment of FIGS. 12 to 14 may be different from the above-described embodiment of FIGS. 5 to 9 in that a display device 10 may further include an encapsulation pattern TFP disposed between a second encapsulation layer 173 and a third encapsulation layer 175 of a thin-film encapsulation layer TFEL.

The thin-film encapsulation layer TFEL of the display device 10 according to the embodiment may include a first encapsulation layer 171, a second encapsulation layer 173, a third encapsulation layer 175, and an encapsulation pattern TFP.

The encapsulation pattern TFP may be disposed between the second encapsulation layer 173 and the third encapsulation layer 175. The encapsulation pattern TFP may overlap each of the light-emitting areas LA1, LA2 and LA3. In the encapsulation pattern TFP, light emitted from the light-emitting elements ED1, ED2 and ED3 may substantially exit to the wavelength conversion layer WCL. Accordingly, the encapsulation pattern TFP may be disposed to cover at least each of the light-emitting areas LA1, LA2 and LA3. At least a portion of the encapsulation pattern TFP may overlap the non-light-emitting area NLA. The encapsulation pattern TFP may not overlap the bank 180 of the wavelength conversion layer WCL.

As shown in FIG. 14, the encapsulation pattern TFP may have an area larger than the light-emitting areas LA1, LA2 and LA3. The encapsulation pattern TFP may completely cover each of the light-emitting areas LA1, LA2 and LA3. The encapsulation pattern TFP may be spaced apart from another one and may overlap the first region MOL1 of the second encapsulation layer 173. For example, the encapsulation pattern TFP may completely overlap the first region MOL1.

The encapsulation pattern TFP may contain an inorganic material. For example, the encapsulation pattern TFP may include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. It is, however, to be understood that the disclosure is not limited thereto.

The third encapsulation layer 175 may be disposed on the encapsulation pattern TFP and the second encapsulation layer 173. The third encapsulation layer 175 may be in direct contact with the encapsulation pattern TFP and the second encapsulation layer 173 to cover them.

According to this embodiment, the encapsulation pattern TFP may be disposed on the first region MOL1 of the second encapsulation layer 173 and may be used in a fabricating process of forming the groove GRO in the second region MOL2.

Referring to FIGS. 15 and 16, the first encapsulation layer 171 and the second encapsulation layer 173 of the thin-film encapsulation layer TFEL are sequentially formed on the emission material layer EML. Subsequently, an inorganic material layer CVL is formed on the second encapsulation layer 173. The inorganic material layer CVL may be formed using, but is not limited to, chemical vapor deposition (CVD).

Subsequently, a photoresist pattern PR is formed on the inorganic material layer CVL. The photoresist pattern PR is formed to overlap the region where the first region MOL1 of the second encapsulation layer 173 is to be formed.

Subsequently, the inorganic material layer CVL and the second encapsulation layer 173 are etched using the photoresist pattern PR as a mask. The inorganic material layer CVL and the second encapsulation layer 173 may be etched together using dry etching during an etching process. In doing so, the inorganic material layer CVL that is not masked by the photoresist pattern PR may be removed by the etching. A groove GRO may be formed in the second encapsulation layer 173 by adjusting the etching process conditions to partially etch the second encapsulation layer 173.

Subsequently, the photoresist pattern PR is removed. Second regions MOL2 in which the grooves GRO are formed and first regions MOL1 other than the second regions MOL2 may be formed. An encapsulation pattern TFP may be formed to overlap the first region MOL1 of the second encapsulation layer 173.

This embodiment may be applied in case that the process for forming the groove GRO is performed in another facility during the process of fabricating the thin-film encapsulation layer TFEL. If a substrate SUB is transferred to another facility after the second encapsulation layer 173 has been formed, foreign substances or moisture may permeate into the second encapsulation layer 173. Therefore, the second encapsulation layer 173 may be covered with an inorganic material layer CVL to protect it, and an etching process to form a groove GRO in the second encapsulation layer 173 may be carried out in the facility. Accordingly, it is possible to prevent permeation of foreign substances or moisture into the second encapsulation layer 173 during the process fabricating the thin-film encapsulation layer TFEL and to prevent deterioration of the encapsulation performance.

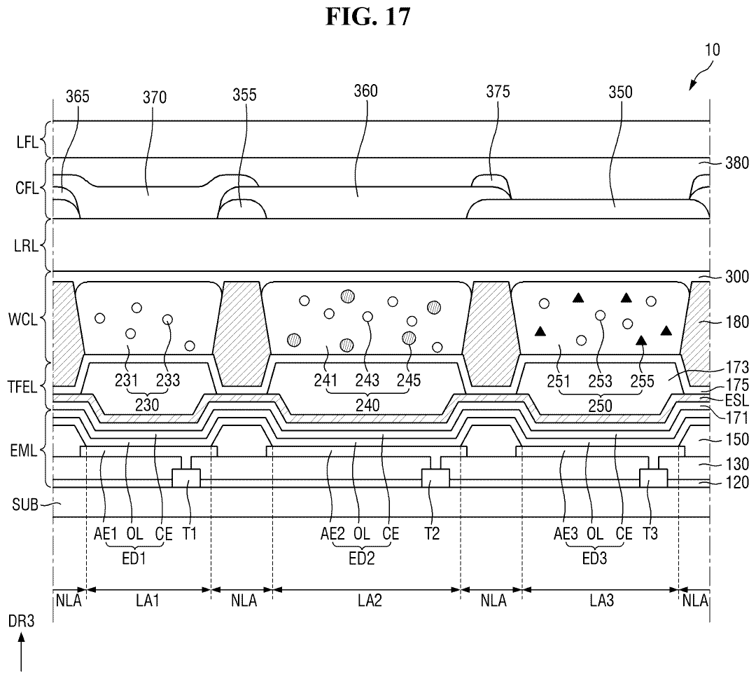

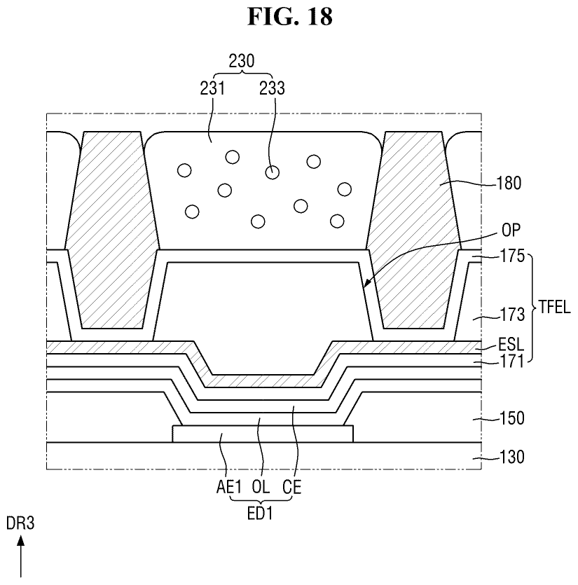

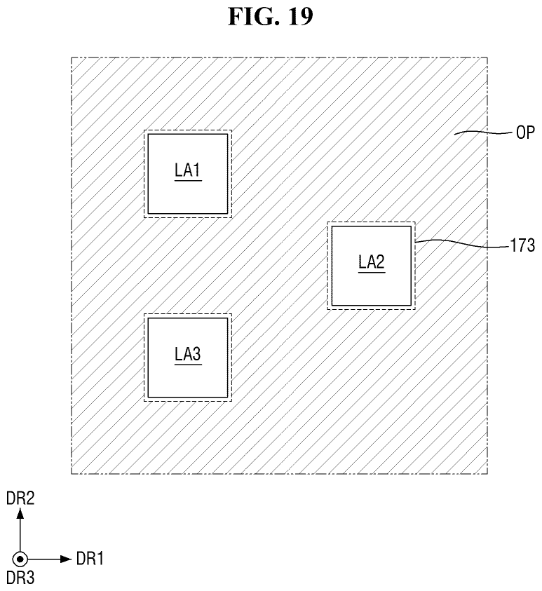

FIG. 17 is a schematic cross-sectional view showing a display device according to an embodiment. FIG. 18 is a schematic cross-sectional view schematically showing a portion of the first light-emitting area of FIG. 17. FIG. 19 is a schematic plan view showing a layout of light-emitting areas of a display device according to an embodiment.

The embodiment of FIGS. 17 to 19 may be different from the above-described embodiment of FIGS. 5 to 9 in that an etch stopper layer ESL may be further disposed between a first encapsulation layer 171 and a second encapsulation layer 173 of a thin-film encapsulation layer TFEL, and the second encapsulation layer 173 may include an opening OP.

The thin-film encapsulation layer TFEL of the display device 10 according to the embodiment may include a first encapsulation layer 171, an etch stopper layer ESL, a second encapsulation layer 173, and a third encapsulation layer 175.

The etch stopper layer ESL may be disposed between the first encapsulation layer 171 and the second encapsulation layer 173. The etch stopper layer ESL may be disposed directly on the first encapsulation layer 171. The etch stopper layer ESL can prevent the underlying layers from being damaged in a process of etching the opening OP of the second encapsulation layer 173, which will be described later. The etch stopper layer ESL may be disposed entirely on the surface of the display area DPA.

The etch stopper layer ESL may be disposed across the light-emitting areas LA1, LA2 and LA3 and accordingly may have high light transmittance. For example, the etch stopper layer ESL may have a transmittance of about 95% or higher with for light with the wavelength of about 550 nm.

The etch stopper layer ESL may contain an inorganic material. For example, the etch stopper layer ESL may include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. The etch stopper layer ESL may include metal oxide. For example, the etch stopper layer ESL may include one or more of indium tin oxide (ITO), indium zinc oxide (IZO), zinc oxide (ZnO), indium tin zinc oxide (ITZO), and indium oxide (In₂O₃). It is, however, to be understood that the disclosure is not limited thereto.

The second encapsulation layer 173 may be disposed on the etch stopper layer ESL. The second encapsulation layer 173 may overlap each of the light emitting area LA1, LA2 and LA3. In the second encapsulation layer 173, light emitted from the light-emitting elements ED1, ED2 and ED3 may substantially exit to the wavelength conversion layer WCL. Accordingly, the second encapsulation layer 173 may be disposed to cover at least each of the light-emitting areas LA1, LA2 and LA3. At least a portion of the second encapsulation layer 173 may overlap the non-light-emitting area NLA. The second encapsulation layer 173 may overlap the bank 180 of the wavelength conversion layer WCL at least partially.

The opening OP may not overlap any of the light-emitting areas LA1, LA2, and LA3. The opening OP may be located between the light-emitting areas LA1, LA2, and LA3. The opening OP may be located to overlap the non-light-emitting area NLA. According to an embodiment, the opening OP may completely overlap the non-light-emitting area NLA. The opening OP may overlap the bank 180 of the wavelength conversion layer WCL.

The opening OP may expose the upper surface of the etch stopper layer ESL thereunder. In the non-light-emitting area NLA, the third encapsulation layer 175 may be in direct contact with the upper surface of the etch stopper layer ESL through the opening OP. The second encapsulation layer 173 may be disposed between the first encapsulation layer 171 and the third encapsulation layer 175 and may be completely covered by them.

The opening OP may be filled with the bank 180. Since the second encapsulation layer 173 is not disposed in the opening OP, the bank 180 may be disposed closer to the pixel-defining layer 150. In other words, the bank 180 may be extended further toward the bottom. Accordingly, lights exiting between adjacent light-emitting areas LA1, LA2 and LA3 can be further blocked to prevent color mixing.

Referring to FIG. 19, the second encapsulation layer 173 may be arranged in a pattern. For example, the second encapsulation layer 173 may be spaced apart from another one and may be arranged in a dot pattern. The second encapsulation layer 173 may have an area larger than each of the light-emitting areas LA1, LA2 and LA3. The second encapsulation layer 173 may completely cover each of the light-emitting areas LA1, LA2 and LA3. The opening OP may not overlap any of the light-emitting areas LA1, LA2, and LA3, and may be disposed except the second encapsulation layer 173. For example, the opening OP may surround the second encapsulation layer 173.

The opening OP described above may be formed via an ashing process after the second encapsulation layer 173 has been formed. The ashing process may be carried out using O₂ or F as a reaction gas. For example, the ashing process may be carried out with O2 reaction gas alone, F reaction gas alone, or with O2 reaction gas followed by a subsequent ashing process with F reaction gas. The ashing process using O2 reaction gas allows for anisotropic etching, and the ashing process using F reaction gas can quickly remove the second encapsulation layer 173, which can save the process time.

According to this embodiment, by forming the etch stopper layer ESL in the thin-film encapsulation layer TFEL, it is possible to prevent the underlying layers from being damaged in case that the opening OP of the second encapsulation layer 173 is etched.

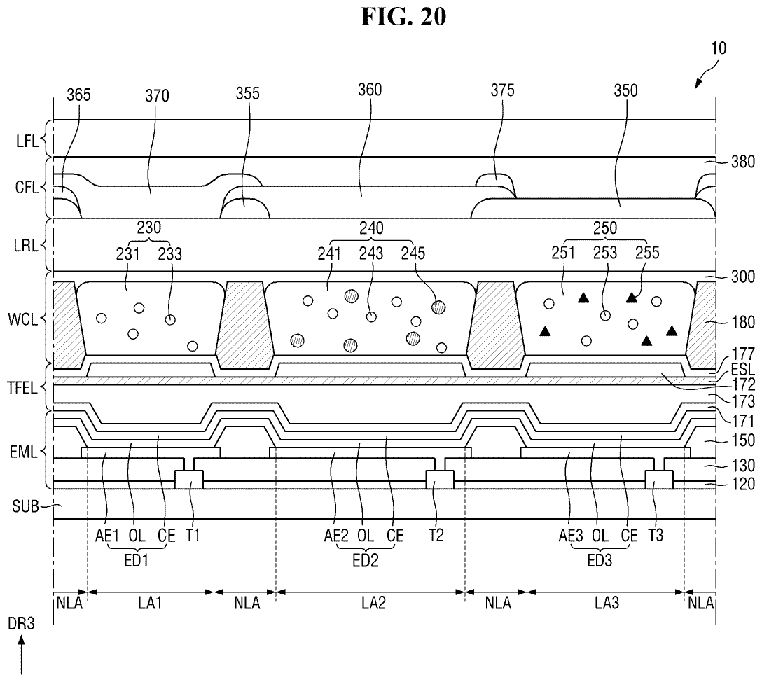

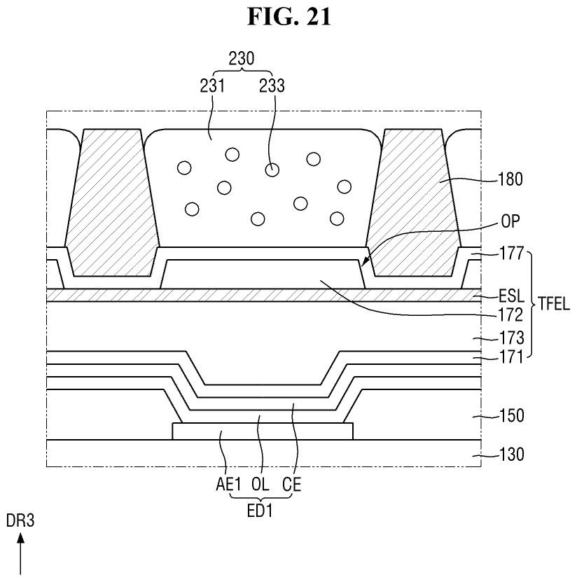

FIG. 20 is a schematic cross-sectional view showing a display device according to an embodiment. FIG. 21 is a schematic cross-sectional view schematically showing a portion of the first light-emitting area of FIG. 20.

The embodiment according to FIGS. 20 and 21 is substantially identical to the above-described embodiment of FIGS. 10 and 11 except that a thin-film encapsulation layer TFEL in a display device 10 may include an etch stopper layer ESL instead of a third encapsulation layer 175, and that a fourth encapsulation layer 172 may include an opening OP; and, therefore, the redundant descriptions will be omitted.

The thin-film encapsulation layer TFEL of the display device 10 according to the embodiment may include a first encapsulation layer 171, a second encapsulation layer 173, an etch stopper layer ESL, a fourth encapsulation layer 172 and a fifth encapsulation layer 177.

The first encapsulation layer 171 may be disposed on the emission material layer EML, and the second encapsulation layer 173 may be disposed on the first encapsulation layer 171. The second encapsulation layer 173 may provide a flat upper surface over the underlying elements having different heights.

The etch stopper layer ESL may be disposed on the second encapsulation layer 173. The etch stopper layer ESL may be flat due to the second encapsulation layer 173 having the flat upper surface. The etch stopper layer ESL can prevent the underlying layers from being damaged in a process of etching the opening OP of the fourth encapsulation layer 172. The etch stopper layer ESL may be disposed entirely on the surface of the display area DPA. The descriptions of the other features of the etch stopper layer ESL will be omitted to avoid redundancy.

The fourth encapsulation layer 172 may be disposed on the etch stopper layer ESL, and the fifth encapsulation layer 177 may be disposed on the fourth encapsulation layer 172.

The fourth encapsulation layer 172 may overlap each of the light emitting area LA1, LA2 and LA3. In the fourth encapsulation layer 172, light emitted from the light-emitting elements ED1, ED2 and ED3 may substantially exit to the wavelength conversion layer WCL. Accordingly, the fourth encapsulation layer 172 may be disposed to cover at least each of the light-emitting areas LA1, LA2 and LA3. At least a portion of the fourth encapsulation layer 172 may overlap the non-light-emitting area NLA. The fourth encapsulation layer 172 may overlap the bank 180 of the wavelength conversion layer WCL at least partially.

The opening OP may not overlap any of the light-emitting areas LA1, LA2, and LA3. The opening OP may be located between the light-emitting areas LA1, LA2, and LA3. The opening OP may be located to overlap the non-light-emitting area NLA. According to an embodiment, the opening OP may completely overlap the non-light-emitting area NLA. The opening OP may be in line with the bank 180 of the wavelength conversion layer WCL.

The opening OP may expose the upper surface of the etch stopper layer ESL thereunder. The fifth encapsulation layer 177 disposed on the fourth encapsulation layer 172 may be in direct contact with the upper surface of the etch stopper layer ESL through the opening OP. The fourth encapsulation layer 172 may be disposed between the etch stopper layer ESL and the fifth encapsulation layer 177 and may be completely covered by them.

The opening OP described above may be formed via an ashing process after the fourth encapsulation layer 172 has been formed. The layout of the fourth encapsulation layer 172 and the opening OP when viewed from the top is identical to the layout of the second encapsulation layer 173 and the opening OP in FIGS. 17 to 19 described above; and, therefore, the redundant descriptions will be omitted.

According to this embodiment, by forming the etch stopper layer ESL in the thin-film encapsulation layer TFEL, it is possible to prevent the underlying layers from being damaged in case that the opening OP of the fourth encapsulation layer 172 is etched.

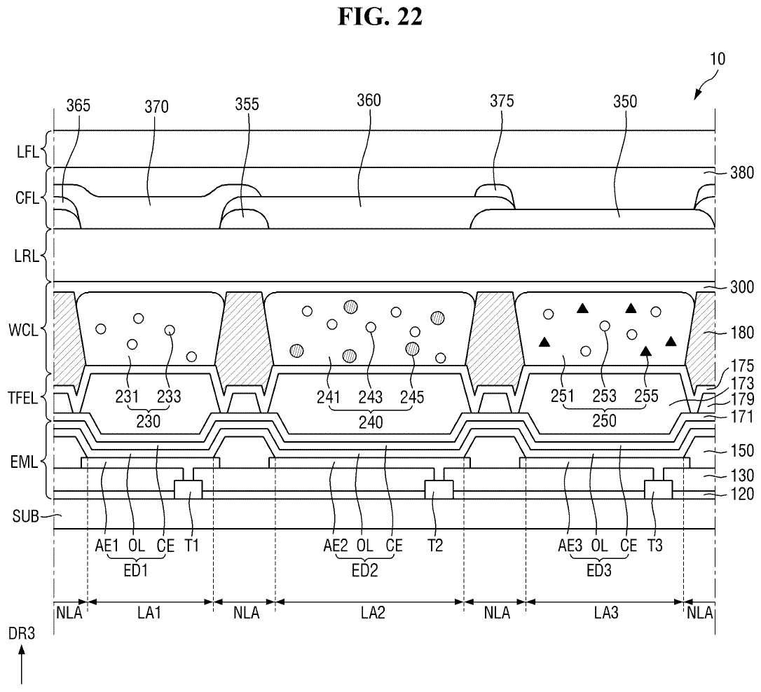

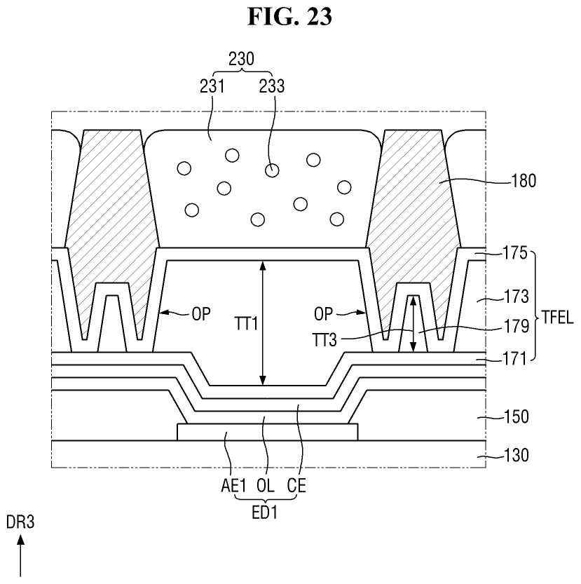

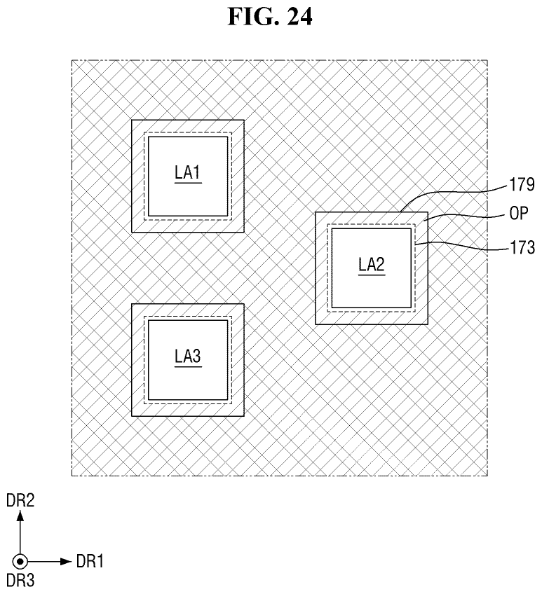

FIG. 22 is a schematic cross-sectional view schematically showing a display device according to an embodiment. FIG. 23 is a schematic cross-sectional view schematically showing a portion of the first light-emitting area of FIG. 22. FIG. 24 is a schematic plan view showing a layout of light-emitting areas of a display device according to an embodiment.

The embodiment of FIGS. 22 to 24 may be different from the above-described embodiment of FIGS. 5 to 9 in that a thin-film encapsulation layer TFEL in a display device 10 may include openings OP, and that an organic layer 179 is disposed in the openings OP. The following description will focus on the differences and the redundant description will be omitted.

The thin-film encapsulation layer TFEL of the display device 10 according to the embodiment may include a first encapsulation layer 171, a second encapsulation layer 173, a third encapsulation layer 175, and an organic layer 179.

The second encapsulation layer 173 may be disposed on the first encapsulation layer 171. The second encapsulation layer 173 may overlap each of the light emitting area LA1, LA2 and LA3. In the second encapsulation layer 173, light emitted from the light-emitting elements ED1, ED2 and ED3 may substantially exit to the wavelength conversion layer WCL. Accordingly, the second encapsulation layer 173 may be disposed to cover at least each of the light-emitting areas LA1, LA2 and LA3. At least a portion of the second encapsulation layer 173 may overlap the non-light-emitting area NLA. The second encapsulation layer 173 may overlap the bank 180 of the wavelength conversion layer WCL at least partially.

The openings OP may not overlap any of the light-emitting areas LA1, LA2, and LA3. The openings OP may be located between the light-emitting areas LA1, LA2, and LA3. The openings OP may be located to overlap the non-light-emitting area NLA. According to an embodiment, the openings OP may completely overlap the non-light-emitting area NLA. The openings OP may overlap the bank 180 of the wavelength conversion layer WCL.

The openings OP may expose the upper surface of the first encapsulation layer 171 thereunder. The third encapsulation layer 175 disposed on the second encapsulation layer 173 may be in direct contact with the upper surface of the first encapsulation layer 171 through the openings OP. The second encapsulation layer 173 may be disposed between the first encapsulation layer 171 and the third encapsulation layer 175 and may be completely covered by them.

An organic layer 179 may be disposed in the openings OP. The organic layer 179 may be disposed directly on the first encapsulation layer 171 or between the first encapsulation layer 171 and the third encapsulation layer 175. The organic layer 179 may be completely covered by the first encapsulation layer 171 and the third encapsulation layer 175 therebetween, it is thus possible to prevent moisture from permeating into the organic layer 179.

The organic layer 179 may not overlap any of the light-emitting areas LA1, LA2, and LA3. The organic layer 179 may be disposed between the light-emitting areas LA1, LA2, and LA3. The organic layer 179 may overlap the non-light-emitting area NLA. According to an embodiment, the organic layer 179 may completely overlap the non-light-emitting area NLA. The organic layer 179 may overlap the bank 180 of the wavelength conversion layer WCL.

The organic layer 179 may have a third thickness TT3. The second encapsulation layer 173 may have a first thickness TT1, and the third thickness TT3 of the organic layer 179 may be smaller than the first thickness TT1. For example, the third thickness TT3 of the organic layer 179 may range from about 50% to about 90% of the first thickness TT1.

As shown in FIG. 24, the opening OP may not overlap each of the light-emitting areas LA1, LA2 and LA3, and may surround each of the light-emitting areas LA1, LA2 and LA3. The organic layer 179 may have an area smaller than the area of the opening OP, may not overlap any the light-emitting areas LA1, LA2 and LA3, and may surround each of the light-emitting areas LA1, LA2 and LA3. For example, the second encapsulation layer 173 may be arranged in a dot pattern similar to the shape of the light-emitting areas LA1, LA2 and LA3, and the organic layer 179 may surround the second encapsulation layer 173.

The opening OP may be filled with the bank 180, which covers the organic layer 179. Since the second encapsulation layer 173 is not disposed in the opening OP, the bank 180 may be disposed closer to the pixel-defining layer 150. In other words, the bank 180 may be extended further toward the bottom. Accordingly, lights exiting between adjacent light-emitting areas LA1, LA2 and LA3 can be further blocked to prevent color mixing.

Table 1 below shows the emission efficiency and color gamut of red, green, blue and white depending on whether a second encapsulation layer of a thin-film encapsulation layer has a groove or not. The emission efficiency and the color gamut in Table 1 below are simulation results. The structure in which grooves are formed in the second encapsulation layer is identical to the structure of FIGS. 5 and 6, and the depth of the grooves was 1.5 μm.

TABLE 1

| | Emission Efficiency (%) | | | | Color Gamut (%) |
|---|---|---|---|---|---|
| Groove | R | G | B | W | DCI |
| X | 100 | 100 | 100 | 100 | 98.15 |
| ◯ | 96.7 | 99.3 | 93.2 | 98.4 | 99.01 |

Referring to Table 1 above, comparing the structure in which grooves are formed in the second encapsulation layer with the structure in which no groove is formed in the second encapsulation layer, the color gamut was improved from about 98.15% to about 99.01%.

Accordingly, it can be seen from the above that the display device according to this embodiment can increase the color gamut by forming grooves in the second encapsulation layer and disposing the bank on the grooves.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a first electrode disposed on a substrate;
a pixel-defining layer that covers an edge of the first electrode and defines light-emitting areas and a non-light-emitting area;
a light emitting layer disposed on the first electrode and the pixel-defining layer;
a second electrode disposed on the light emitting layer;
a thin-film encapsulation layer disposed on the second electrode, the thin-film encapsulation layer comprising a first encapsulation layer, a second encapsulation layer disposed on the first encapsulation layer, and a third encapsulation layer disposed on the second encapsulation layer; and
a wavelength conversion layer disposed on the thin-film encapsulation layer, the wavelength conversion layer comprising a bank overlapping the non-light-emitting area, wherein
the second encapsulation layer comprises first regions overlapping the light-emitting areas and second regions not overlapping the light-emitting areas, and
a thickness of the first regions is greater than a thickness of the second regions.

2. The display device of claim 1, wherein
the first regions overlap the non-light-emitting area, and
the second regions overlap the non-light-emitting area.

3. The display device of claim 1, wherein the first regions do not overlap the bank and the second regions overlap the bank.

4. The display device of claim 1, wherein the thickness of the second regions is in a range of about 50% to about 90% of the thickness of the first regions.

5. The display device of claim 1, wherein
the second encapsulation layer comprises a groove formed in a surface of the second encapsulation layer, and
the groove is disposed in the second regions.

6. The display device of claim 1, wherein
the first regions cover the light-emitting areas and are spaced apart from one another in plan view, and
the second regions are disposed in regions other than the first regions.

7. The display device of claim 1, wherein the second regions are spaced apart from one another and are disposed between light-emitting areas that emit lights of different colors.

8. The display device of claim 1, further comprising:
an encapsulation pattern disposed between the second encapsulation layer and the third encapsulation layer,
wherein the encapsulation pattern overlaps the first regions but does not overlap the second regions.

9. The display device of claim 8, wherein the encapsulation pattern overlaps the light-emitting areas but does not overlap the bank.

10. The display device of claim 1, further comprising:
a fourth encapsulation layer disposed between the first encapsulation layer and the second encapsulation layer; and
a fifth encapsulation layer disposed between the fourth encapsulation layer and the second encapsulation layer, wherein
the first encapsulation layer, the third encapsulation layer and the fifth encapsulation layer contain an inorganic material, and
the second encapsulation layer and the fourth encapsulation layer contain an organic material.

11. The display device of claim 1, wherein
the first encapsulation layer and the third encapsulation layer contain an inorganic material, and
the second encapsulation layer contains an organic material.

12. The display device of claim 1, wherein
the wavelength conversion layer comprises a light-transmitting pattern, a first wavelength conversion pattern and a second wavelength conversion pattern disposed in a space defined by the bank and respectively overlapping the light-emitting areas.

13. The display device of claim 12, further comprising:
a low-refractive layer disposed on the wavelength conversion layer; and
a color filter layer disposed on the low-refractive layer, the color filter layer comprising a first color filter overlapping the light-transmitting pattern, a second color filter overlapping the first wavelength conversion pattern, and a third color filter overlapping the second wavelength conversion pattern.

14. A display device comprising:
a first electrode disposed on a substrate;
a pixel-defining layer that covers an edge of the first electrode and defines light-emitting areas and a non-light-emitting area;
a light emitting layer disposed on the first electrode and the pixel-defining layer;
a second electrode disposed on the light emitting layer;
a thin-film encapsulation layer disposed on the second electrode, the thin-film encapsulation layer comprising a first encapsulation layer, an etch stopper layer disposed on the first encapsulation layer, a second encapsulation layer disposed on the etch stopper layer, and a third encapsulation layer disposed on the second encapsulation layer; and
a wavelength conversion layer disposed on the thin-film encapsulation layer and comprising a bank overlapping the non-light-emitting area,
wherein the third encapsulation layer contacts the etch stopper layer in the non-light-emitting area.

15. The display device of claim 14, wherein
the second encapsulation layer comprises an opening exposing the etch stopper layer, and
the third encapsulation layer contacts the etch stopper layer through the opening of the second encapsulation layer.

16. The display device of claim 15, wherein the opening of the second encapsulation layer overlaps the non-light-emitting area and the bank.

17. The display device of claim 14, wherein the second encapsulation layer is disposed between the etch stopper layer and the third encapsulation layer, and is covered by the etch stopper layer and the third encapsulation layer.

18. The display device of claim 14, further comprising:
a fourth encapsulation layer disposed between the first encapsulation layer and the etch stopper layer,
wherein the second encapsulation layer and the fourth encapsulation layer contain an organic material.

19. A display device comprising:
a first electrode disposed on a substrate;
a pixel-defining layer that covers an edge of the first electrode and defines light-emitting areas and a non-light-emitting area;
a light emitting layer disposed on the first electrode and the pixel-defining layer;
a second electrode disposed on the light emitting layer;
a thin-film encapsulation layer disposed on the second electrode, the thin-film encapsulation layer comprising a first encapsulation layer, a second encapsulation layer and an organic layer disposed on the first encapsulation layer and spaced apart from each other, and a third encapsulation layer disposed on the second encapsulation layer and the organic layer; and
a wavelength conversion layer disposed on the thin-film encapsulation layer, the wavelength conversion layer comprising a bank overlapping the non-light-emitting area,
wherein the third encapsulation layer contacts an etch stopper layer in the non-light-emitting area.

20. The display device of claim 19, wherein
the second encapsulation layer overlaps the non-light-emitting area and the bank, the second encapsulation layer comprises an opening exposing the first encapsulation layer, and
the organic layer is disposed in the opening of the second encapsulation layer and contacts the first encapsulation layer.

21. The display device of claim 20, wherein the third encapsulation layer covers the second encapsulation layer and the organic layer, and contacts the first encapsulation layer through the opening of the second encapsulation layer.

22. The display device of claim 20, wherein the opening of the second encapsulation layer is filled with the bank on the third encapsulation layer.

23. The display device of claim 19, wherein a thickness of the organic layer is less than a thickness of the second encapsulation layer.

24. The display device of claim 19, wherein
the first encapsulation layer and the third encapsulation layer contain an inorganic material, and
the second encapsulation layer contains an organic material.
